(19) United States
(12) Patent Application Publication
(10) Pub. No.: US 2009/0017621 A1
(43) Pub. Date: Jan. 15, 2009

(54) Manufacturing method for semiconductor device and manufacturing device of semiconductor device

(75) Inventors: Takuji Sako, Albany, NY (US); Kaoru Maekawa, Albany, NY (US)

Correspondence Address: MASUVALLEY & PARTNERS, 8765 AERO DRIVE, SUITE 312, SAN DIEGO, CA, 92123, US

(73) Assignee: Tokyo Electron Limited, Tokyo (JP)

(21) Appl. No.: 12/217,202

(22) Filed: Jul. 1, 2008

(30) Foreign Application Priority Data
Jul. 4, 2007 (JP) JP2007-176004

(51) Int. Cl. H01L 21/768; H01L 21/67

(52) U.S. Cl. 438/674; 118/722; 257/E21.575

(57) ABSTRACT

The semiconductor manufacturing method includes the step (ST.1) of preparing a semiconductor substrate with a copper or copper-containing metal film exposed on a surface, step (ST.2) of depositing on the copper or copper-containing metal film a metal film consisting essentially of any one of CoWB, CoWP, or W; step (ST.3) of introducing Si into the above-described metal film, and step (ST.4) of nitriding the metal film introduced with Si.

### FIELD OF THE INVENTION

The present invention relates to a semiconductor device manufacturing method, and more particular to a method for manufacturing a semiconductor device having a copper or copper-containing metal film, and semiconductor device manufacturing apparatus used for the manufacturing method.

### BACKGROUND OF THE INVENTION

In recent times, as an increase in speed of semiconductor devices, miniaturization of wiring patterns, and increase in integration level are required, improvement of electrical conductivity of wiring is also required, and in response to this, copper (Cu) of which electrical conductivity is higher than those of aluminum (Al) and tungsten (W) is employed.

However, Cu is likely to be oxidized to form fragile copper oxide, and therefore adhesiveness and mechanical strength are likely to be reduced. Also, Cu is likely to be diffused, and a short circuit between wiring lines occurs due to the diffusion into an interlayer insulation film. For this reason, as a barrier film for an upper wiring part, an insulation film such as silicon nitride (SiN) has conventionally been used; however, it has a high relative dielectric constant, which causes an increase in inter-wiring capacity, resulting in an obstacle to the increase of the device speed. On the other hand, as one of methods for solving the obstacle, there is a method that employs a metal film excellent in oxidation resistance and Cu-barrier property only for the upper wiring part. Candidates for the metal film include a tungsten (W) film and a cobalt-tungsten (CoW) based metal film (hereinafter referred to as a cap metal film).

However, for example, if the CoW based metal film is used as the cap metal film, there arise some circumstances including:
As a thickness is reduced to 20 nm or less, the Cu-barrier property becomes poor (refer to X. Wang, AMC04, p. 809-814 (2004)), and
Prevention of oxidation of Cu becomes difficult (refer to Japanese published unexamined patent application No. 2002-367998).

As a method for improving such circumstances, there is disclosed a method in which the CoW based metal film is nitrided to enhance the Cu-barrier property (refer to Japanese published unexamined patent application No. 2006-253666).

However, in order to sufficiently nitride the CoW based metal film, a W content should be increased. If the W content is increased in the CoW based metal film, there arise problems including:
A deposition rate such as a plating rate is decreased, resulting in a reduction in productivity,
Uniformity of the film is deteriorated because of reaction sensitive to a state of a Cu film property, and
Adhesiveness to surrounding films such as an etching stopper film formed on the cap metal film is poor
   (refer to Japanese published unexamined patent application No. 2003-124217).

Note that siliciding the cap metal film is described in Japanese published unexamined patent application No. 2003-243392, and metal nitride silicide serving as the barrier film is described in Japanese published unexamined patent application No. 2003-243498.

### SUMMARY OF THE INVENTION

The present invention has an object to provide a method for manufacturing a semiconductor device having a copper protective film that has good barrier property against copper and causes both of good productivity and good adhesiveness to a surrounding film, and semiconductor device manufacturing apparatus used for the manufacturing method.

In order to solve the above-described problems, a semiconductor device manufacturing method according to a first aspect of the present invention includes the steps of: preparing a semiconductor substrate with a copper or copper-containing metal film exposed on a surface; depositing a metal film consisting essentially of either cobalt-tungsten based metal (CoW) or tungsten (W) on said copper or copper-containing metal film; introducing Si into said metal film; and nitriding said metal film introduced with Si.

Also, semiconductor device manufacturing apparatus according to a second aspect of the present invention includes a chamber, wherein the chamber includes a depositing means adapted to deposit a metal film consisting essentially of tungsten (W) on a copper or copper-containing metal film exposed on a surface of a semiconductor substrate; an introducing means adapted to introduce Si into said metal film, and a nitriding means adapted to nitride said metal film introduced with Si.

Further, semiconductor device manufacturing apparatus according to a third aspect of the present invention includes a first chamber provided with a depositing means adapted to deposit a metal film consisting essentially of tungsten (W) on a copper or copper-containing metal film exposed on a surface of a semiconductor substrate and an introducing means adapted to introduce Si into said metal film, a second chamber provided with a nitriding means adapted to nitride said metal film introduced with Si, and a carrying mechanism adapted to carry said semiconductor substrate with vacuum being held between said first chamber and said second chamber.

Still further, semiconductor device manufacturing apparatus according to a fourth aspect of the present invention includes, a first chamber provided with a depositing means adapted to deposit a metal film consisting essentially of any of cobalt-tungsten based metal (CoW) or tungsten (W) on a copper or copper-containing metal film exposed on a surface of a semiconductor substrate; a second chamber provided with an introducing means adapted to introduce Si into said metal film and a nitriding means adapted to nitride said metal film introduced with Si; and a carrying mechanism adapted to carry said semiconductor substrate between said first chamber and said second chamber.

Yet further, semiconductor device manufacturing apparatus according to a fifth aspect of the present invention includes a first chamber provided with a depositing means adapted to deposit a metal film consisting essentially of any of cobalt-tungsten based metal (CoW) or tungsten (W) on a copper or copper-containing metal film exposed on a surface of a semiconductor substrate, a second chamber provided with an introducing means adapted to introduce Si into said metal film, a third chamber provided with a nitriding means adapted to nitride said metal film introduced with Si, and a carrying mechanism adapted to carry said semiconductor substrate with vacuum being held at least between said second chamber and said third chamber of between said first chamber and said second chamber and between said second chamber and said third chamber.

According to the present invention, there can be provided a method for manufacturing a semiconductor device having a copper protective film that has good barrier property against copper and causes both of good productivity and good adhesiveness to a surrounding film, and semiconductor device manufacturing apparatus used for the manufacturing method.

### BRIEF DESCRIPTION OF THE DRAWINGS

FIG. 1 is a flowchart illustrating a basic flow of a semiconductor device manufacturing method according to a first embodiment of the present invention.

FIG. 2 is a cross-sectional view schematically illustrating an example of an electroless plating machine according to a second embodiment of the present invention.

FIG. 3 is a cross-sectional view schematically illustrating an example of thermal deposition apparatus according to the second embodiment of the present invention.

FIG. 4 is a cross-sectional view schematically illustrating an example of thermal deposition apparatus according to the second embodiment of the present invention.

FIG. 5 is a cross-sectional view schematically illustrating an example of plasma deposition apparatus according to the second embodiment of the present invention.

FIG. 6 is a cross-sectional view schematically illustrating an example of plasma deposition apparatus according to the second embodiment of the present invention.

FIG. 7 is a cross-sectional view schematically illustrating an example of RLSA microwave plasma deposition apparatus according to the second embodiment of the present invention.

FIG. 8 is a cross-sectional view schematically illustrating an example of catalytic deposition apparatus according to the second embodiment of the present invention.

FIG. 9 is a flowchart illustrating an example of a semiconductor device manufacturing method according to a third embodiment of the present invention.

FIGS. 10A to 10F are cross-sectional views illustrating an example of the semiconductor device manufacturing method according to the third embodiment of the present invention on the basis of respective major manufacturing steps.

FIGS. 11A to 11F are diagrams illustrating schematic configurations of first to sixth manufacturing apparatus according to a fourth embodiment of the present invention.

FIG. 12 is a cross-sectional view schematically illustrating a first example of the first manufacturing apparatus.

FIG. 13 is a cross-sectional view schematically illustrating a second example of the first manufacturing apparatus.

FIG. 14 is a cross-sectional view schematically illustrating a third example of the first manufacturing apparatus.

FIG. 15 is a horizontal cross-sectional view illustrating an example of a configuration of the second manufacturing apparatus.

FIG. 16 is a horizontal cross-sectional view illustrating an example of a configuration of the third manufacturing apparatus.

FIG. 17 is a horizontal cross-sectional view illustrating an example of a configuration of the fourth manufacturing apparatus.

FIG. 18 is a horizontal cross-sectional view illustrating an example of a configuration of the fifth manufacturing apparatus.

FIG. 19 is a horizontal cross-sectional view illustrating an example of a configuration of the sixth manufacturing apparatus.

### EXPLANATION OF LETTERS OR NUMERALS

1: Si substrate, 2: Interlayer insulation film, 3: Dielectric film, 4: Interlayer insulation film, 5: Cu wiring, 6: Barrier metal layer, 7: Metal film (cap metal film), 7a: Silicon-containing cap metal film, 7b: Nitride silicide cap metal film, and 8: Dielectric film.

### DETAILED DESCRIPTION OF THE INVENTION

Some of embodiments of the present invention will hereinafter be described with reference to the drawings. In the description, the same portions are denoted by the same reference symbols throughout the diagrams.

### First Embodiment

A first embodiment is one illustrating a basic flow of a semiconductor device manufacturing method according to the present invention.

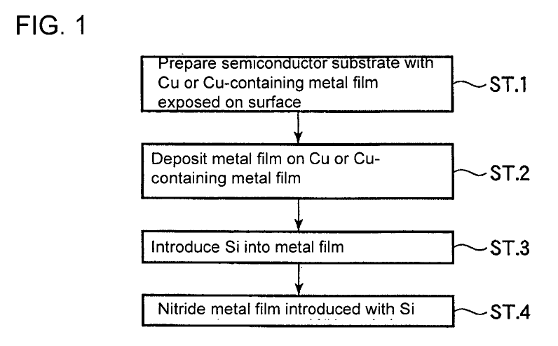

FIG. 1 is a flowchart illustrating a flow of a semiconductor device manufacturing method according to the first embodiment of the present invention.

First, as indicated by ST.1 in FIG. 1, a semiconductor substrate with a copper or copper-containing metal film exposed on a surface thereof is prepared.

Then, as indicated by ST.2, a metal film is deposited on the copper (Cu) or Cu-containing metal film. The metal film in an embodiment of the present invention is selected from any of cobalt-tungsten (CoW) based metal, or tungsten (W). Examples of the cobalt-tungsten (CoW) based metal include cobalt-tungsten-boron (CoWB), and cobalt-tungsten-phosphorus (CoWP).

Subsequently, as indicated by ST.3, Si is introduced into the metal film.

After that, as indicated by ST.4, the metal film introduced with Si is nitrided. The metal film that is introduced with Si and nitrided can be used as a Cu protective film (cap metal film) having barrier property against Cu.

According to the above-described manufacturing method, the metal film consisting essentially of the CoW based metal or W is deposited on the Cu or Cu-containing metal film, and is then nitrided. For this reason, the cap metal film formed according to the flow illustrated in FIG. 1 can have good barrier property against Cu.

Also, according to the above-described manufacturing method, prior to the nitridation of the metal film, silicon (Si) is introduced into the metal film. For this reason, a W content in the metal film can be reduced as compared with the case where Si is not introduced. The reduction in W content enables a film forming rate of the metal film, such as a plating rate or deposition rate, to be increased, as compared with the case where Si is not introduced into the metal film. Accordingly, the cap metal film formed according to the flow illustrated in FIG. 1 causes good productivity.

Also, because the W content is reduced, the metal film can be more uniformly deposited without largely depending on a state of a Cu film property. For this reason, the cap metal film formed according to the flow illustrated in FIG. 1 has improved uniformity, as compared with the case where Si is not introduced into the metal film.

Further, because Si is introduced into the metal film, adhesiveness between the metal film and a Si-containing insulation film such as SiN, SiCN, or SiC is improved, as compared with the case where Si is not introduced. The Si-containing insulation film is a film formed around the cap metal film, which is widely used as an etching stopper film or the like. Accordingly, the cap metal film formed according to the flow illustrated in FIG. 1 has good adhesiveness to the surrounding film.

As described, according to the semiconductor device manufacturing apparatus relating to the first embodiment, there can be obtained a method for manufacturing a semiconductor device having a cap metal film that has good barrier property against Cu and causes both of good productivity and good adhesiveness to a surrounding film.

Next, examples of both specific manufacturing apparatus used in the above-described basic flow and a specific manufacturing method using the above-described basic flow are sequentially described as second and subsequent embodiments.

### Second Embodiment

A second embodiment relates to a specific example of the semiconductor device manufacturing apparatus.

(Metal Film Deposition Apparatus)

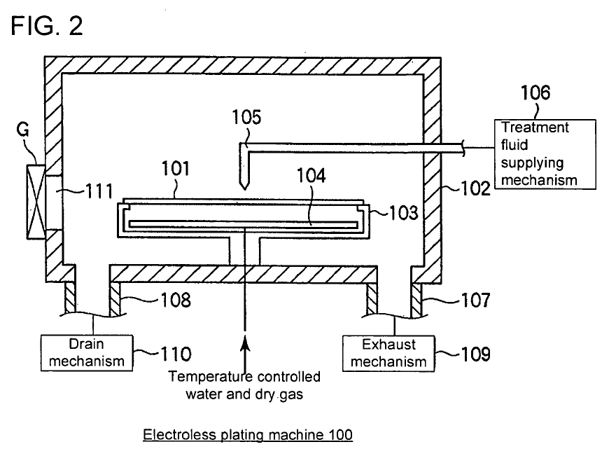

FIG. 2 is a cross-sectional view schematically illustrating an example of an electroless plating machine.

The electroless plating machine illustrated in FIG. 2 can be used for the metal film deposition step indicated by ST.2 in FIG. 1, particularly if the metal film is formed of CoWB or CoWP.

As illustrated in FIG. 2, the electroless plating machine 100 has a substantially cylindrical chamber 102, which contains a semiconductor substrate 101 and can hold the inside thereof in vacuum.

On the bottom of the chamber 102, a spin chuck 103 is provided. The semiconductor substrate (semiconductor wafer) 101 is supported by the spin chuck 103. Inside the spin chuck 103, a vertically movable underplate 104 is provided. The underplate 104 supplies temperature controlled water such as temperature controlled pure water, and dry gas such as temperature controlled nitrogen gas to the semiconductor substrate 101. The semiconductor substrate 101 supported by the spin chuck 103 is heated to or dried at a desired temperature by the underplate 104.

A sidewall of the chamber 102 is provided with a nozzle 105 extending above the semiconductor substrate 101. The nozzle 105 is connected to a treatment fluid supplying mechanism 106. The treatment fluid supplying mechanism 106 supplies a chemical solution such as a cleaning solution, a plating solution for deposition, and dry gas such as nitrogen gas to the semiconductor substrate 101. The electroless plating deposits the metal film by soaking the semiconductor substrate 101 in the plating solution containing metal ions to reduce the metal ions. For this purpose, the plating solution contains, in addition to the metal ions, a reducing agent for reducing the metal ions. As an example of the reducing agent, for example, if CoWP is deposited, hypophosphorous acid, dimethylamine borane, or the like can be used.

Also, in the plating deposition, the metal film is selectively grown on the Cu or Cu-containing metal film, and therefore can be grown with being self-aligned with the Cu or Cu-containing metal film.

The bottom of the chamber 102 is connected with an exhaust pipe 107 and a drain pipe 108. The exhaust pipe 107 is connected to an exhaust mechanism 109 including a vacuum pump, valve, and the like for exhausting the chamber 102, and the drain pipe 108 is connected to a drain mechanism 110 including a vacuum pump, valve, and the like for recovering the chemical or plating solution from inside the chamber 102.

The sidewall of the chamber 102 is provided with a carry in/out port 111 for carrying in/out the semiconductor substrate 101 to/from the inside of the chamber 102. The carry in/out port 111 is adapted to be openable and closable by a gate valve G.

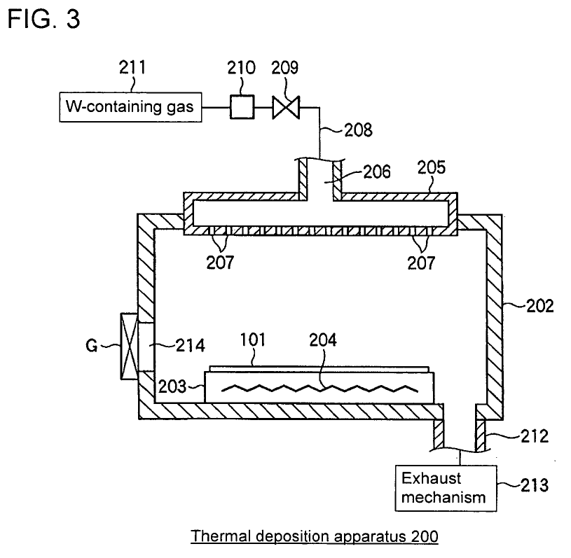

FIG. 3 is a cross-sectional view schematically illustrating an example of thermal deposition apparatus.

The thermal deposition apparatus illustrated in FIG. 3 is one based on a chemical vapor deposition method, and can be used for the metal film deposition step indicated by ST.2 in FIG. 1, particularly if the metal film is formed of W.

As illustrated in FIG. 3, the thermal deposition apparatus 200 has a substantially cylindrical chamber 202, which contains the semiconductor substrate 101 and can hold the inside thereof in vacuum.

The bottom of the chamber 202 is provided with a susceptor 203. The semiconductor substrate 101 is placed on the susceptor 203. Inside the susceptor 203, a heater 204 is buried, and adapted to heat the semiconductor substrate 101 placed on the susceptor 203 to a desired temperature.

The top of the chamber 202 is provided with a hollow disk-shaped showerhead 205 such that the showerhead 205 faces to the susceptor 203. The showerhead 205 introduces deposition gas, i.e., W-containing gas in the present embodiment, into the chamber 202. In the center of an upper surface of the showerhead 205, a gas inlet 206 is provided, and a lower surface of the showerhead 205 is provided with a plurality of gas discharge holes 207. The gas inlet 206 is connected to one end of a gas supplying line 208, and the other end of the gas supplying line 208 is connected to a deposition gas supply source 211 through an opening/closing valve 209 and a flow rate controller 210 such as a mass flow controller. The deposition gas supply source 211 supplies the W-containing gas in the present embodiment. One example of the W-containing gas is tungsten fluoride (e.g., WF₆). Also, W is selectively deposited on the Cu or Cu-containing metal film, and therefore, similarly to the plating deposition, can be grown with being self-aligned with the Cu or Cu-containing metal film.

The bottom of the chamber 202 is connected with an exhaust pipe 212. The exhaust pipe 212 is connected to an exhaust mechanism 213 including a valve, vacuum pump, and the like for exhausting the chamber 202.

A sidewall of the chamber 202 is provided with a carry in/out port 214 for carrying in/out the semiconductor substrate 101 to/from the inside of the chamber 202. The carry in/out port 214 is adapted to be openable and closable by a gate valve G.

The metal film can be deposited by using the electroless plating machine illustrated in FIG. 2 or thermal deposition apparatus illustrated in FIG. 3.

(Si Introduction Apparatus)

When Si is introduced into the metal film, for example, thermal deposition apparatus can be used.

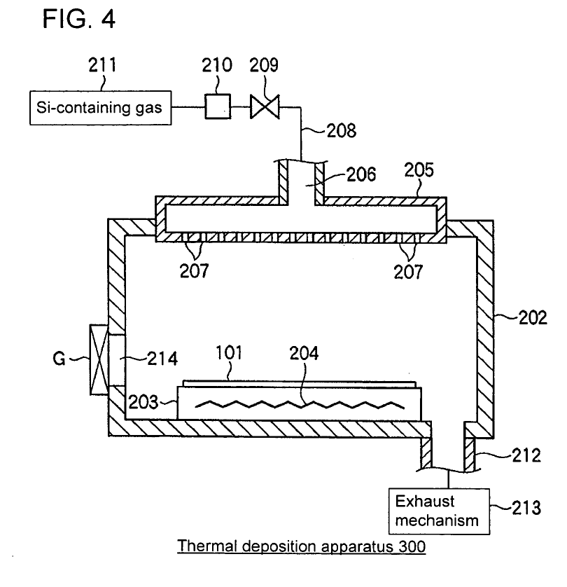

FIG. 4 is a cross-sectional view schematically illustrating an example of the thermal deposition apparatus.

The different point of the thermal deposition apparatus 300 illustrated in FIG. 4 from that 200 illustrated in FIG. 3 is that the deposition gas supply source 211 supplies Si-containing gas. The rest is the same as that in the thermal deposition apparatus 200 illustrated in FIG. 3.

By supplying the Si-containing gas into the chamber 202 through the showerhead 205, Si can be introduced into the unshown metal film formed on the semiconductor substrate 101.

Examples of the Si-containing gas include SiH₄, Si₂H₆, SiH₂Cl₂, Si(CH₃)₄, SiH(CH₃)₃, SiH₂(CH₃)₂, and SiH₃(CH₃) gases.

When Si is introduced into the metal film, any of the above-described Si-containing gases is introduced into the chamber 202; the inside of the chamber 202 is brought into a reduced pressure condition within a pressure range of, for example, 1.3 Pa (abs) or higher and 1333 Pa (abs) or lower (10 mTorr (abs) or higher and 10 Torr (abs) or lower); and a temperature of the substrate 101 is set within a temperature range of, for example 100° C. or higher and 400° C. or lower.

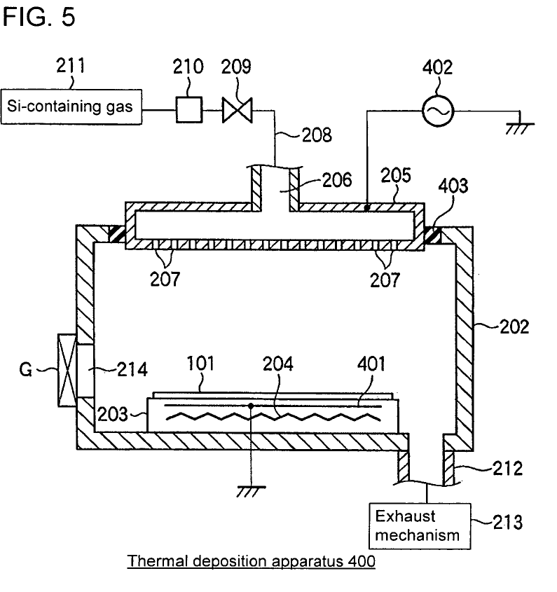

When Si is introduced into the metal film, it is not particularly necessary to form plasma; however, depending on gas, it may be adapted to form plasma to facilitate decomposition. In this case, it is only necessary to use plasma deposition apparatus 400 as illustrated in FIG. 5.

FIG. 5 is a cross-sectional view schematically illustrating an example of the plasma deposition apparatus.

Different points of the plasma deposition apparatus 400 illustrated in FIG. 5 from the thermal deposition apparatus 300 illustrated in FIG. 4 are that an electrode is buried in the susceptor 203; the showerhead 205 is connected with a high frequency power supply 402; and the showerhead 205 is provided in the top of the chamber 202 with being insulated by an insulator 403. The rest is the same as that in the thermal deposition apparatus 300 illustrated in FIG. 4.

When Si is introduced into the metal film, any of the above-described Si-containing gases is introduced into the chamber 202, and high frequency power is applied from the high frequency power supply 402 to the showerhead 205 with the electrode 401 being grounded. This brings the Si-containing gas introduced into the chamber 202 into a plasma state. In addition, pressure inside the chamber 202 may be in a reduced pressure condition similar to that for the case of the thermal deposition apparatus 200. Also, the substrate 101 may be at a temperature similar to that for the case of the thermal deposition apparatus 200. Note that because the Si-containing gas is in the plasma state, the temperature may be set lower than that for the case of the thermal deposition apparatus 200.

Using the thermal deposition apparatus 300 illustrated in FIG. 4 or plasma deposition apparatus 400 illustrated in FIG. 5 enables Si to be introduced into the metal film.

(Nitriding Apparatus)

When the metal film introduced with Si is nitrided, for example, plasma deposition apparatus can be used.

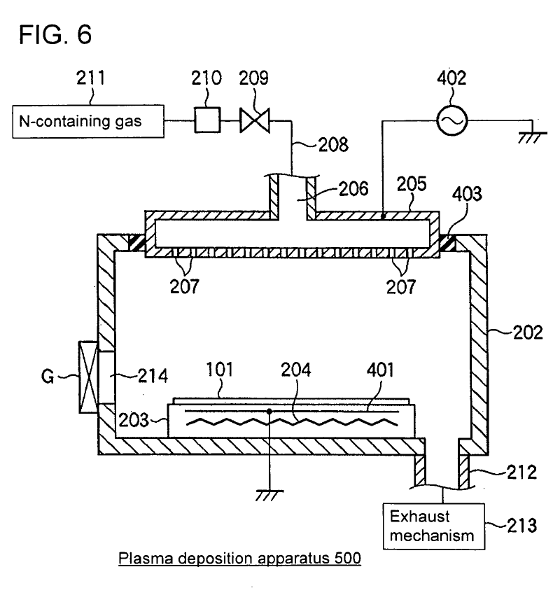

FIG. 6 is a cross-sectional view schematically illustrating an example of the plasma deposition apparatus.

A different point of the plasma deposition apparatus 500 illustrated in FIG. 6 from that 400 illustrated in FIG. 5 is that the deposition gas supply source 211 supplies N-containing gas. The rest is the same as that in the plasma deposition apparatus 400 illustrated in FIG. 5.

Examples of the N-containing gas include N₂ gas only, N₂ gas+Ar gas, N₂ gas+H₂ gas, and NH₃ gas.

When the metal film introduced with Si is nitrided, any of the above-described N-containing gases is introduced into the chamber 202 through the showerhead 205; the inside of the chamber 202 is brought into a reduced pressure condition within a pressure range of, for example, 1.3 Pa (abs) or higher and 1333 Pa (abs) or lower (10 mTorr (abs) or higher and 10 Torr (abs) or lower); and a temperature of the substrate 101 is set within a temperature range of, for example, 100° C. or higher and 400° C. or lower

Further, by applying high frequency power from the high frequency power supply 402 to the showerhead 205 with the electrode 401 being grounded, the N-containing gas introduced into the chamber 202 can be brought into a plasma state to thereby nitride the metal film introduced with Si.

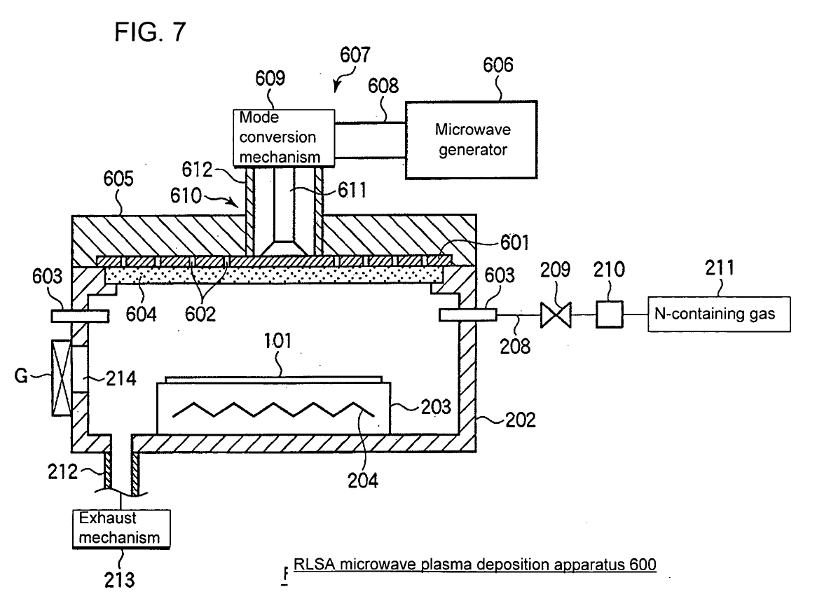

As the plasma nitriding treatment, in addition to a typical plasma nitriding treatment using the apparatus illustrated in FIG. 6, a radical nitriding treatment using plasma including radicals having lower electron temperature and higher density may also be used. When the radial nitridation is performed, for example, RLSA (Radical Line Slot Antenna) microwave plasma deposition apparatus illustrated in FIG. 7 can be used.

FIG. 7 is a cross-sectional view schematically illustrating an example of the RLSA microwave plasma disposition apparatus.

Particularly different points of the RLSA microwave plasma deposition apparatus 600 illustrated in FIG. 7 from the plasma deposition apparatus 500 illustrated in FIG. 6 are that the top of the chamber 202 is provided with a planar antenna 601 having a plurality of microwave transmitting holes 602, instead of the showerhead 205 supplied with the high frequency power, and a gas inlet 603 is provided in a ring-like form along the sidewall of the substantially cylindrical chamber 202.

A lower surface of the planar antenna 601 is provided with a microwave transmitting plate 604 structured by an insulator and an upper surface of the planar antenna 601 is provided with a shield member 605.

The planar antenna 601 is connected with a microwave transmitting mechanism 607 for guiding a microwave generated from a microwave generator 606 to the planar antenna 601.

The microwave transmitting mechanism 607 includes a waveguide 608 for guiding the microwave generated from the microwave generator 606 to a mode conversion mechanism 609, and coaxial waveguide 610 having an internal conductor 611 and external conductor 612 for guiding the microwave mode-converted in the mode conversion mechanism 609 to the planar antenna 601.

When the metal film introduced with Si is nitrided, any of the above-described N-containing gases is introduced into the chamber 202, and the microwave is guided into the chamber 202 through the planar antenna 601 and microwave transmitting plate 604. The N-containing gas is excited by the microwave guided into the chamber 202, and, along with this, brought into a plasma state. For this reason, the plasma including radicals having lower electron temperature and higher density can be generated, as compared with, for example, the case of the plasma deposition apparatus illustrated in FIG. 6. In addition to this, the plasma can be generated, for example, in a limited space region near the microwave transmitting plate 604, and therefore the semiconductor substrate 101 is unlikely to be directly exposed to the plasma. For these reasons, the RLSA microwave plasma deposition apparatus can nitride the metal film introduced with Si with little damage to, for example, an unshown interlayer insulation film and the like formed on the semiconductor substrate 101.

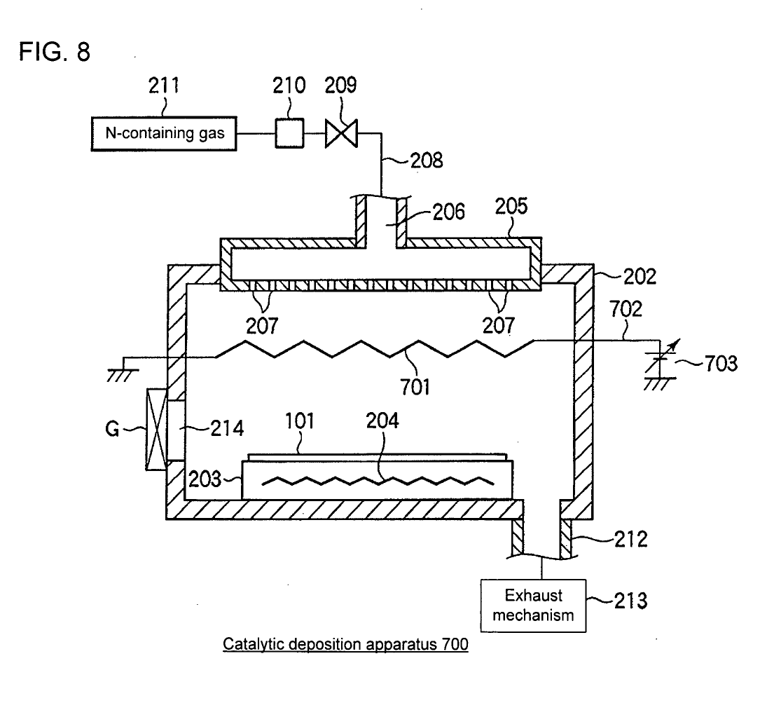

Also, for the radical nitriding treatment, for example, catalytic (Cat) deposition apparatus illustrated in FIG. 8 may be used.

FIG. 8 is a cross-sectional view schematically illustrating an example of the catalytic deposition apparatus.

Different points of the catalytic deposition apparatus 700 illustrated in FIG. 8 from the plasma deposition apparatus 500 illustrated in FIG. 6 are that, because plasma is not used, the catalytic deposition apparatus 700 is adapted to be provided with a heatable catalytic body 701 inside the chamber 202, and a variable DC power supply 703 for providing direct current to the heatable catalytic body 701, instead of the high frequency power supply 402.

The heatable catalytic body 701 is provided between the susceptor 203 and the showerhead 205, and formed of an electrically conductive high melting point material such as W. A shape of the heatable catalytic body 701 is, for example, wire-like. One end of the heatable catalytic body is connected to an electrical supply line 702, and the other end is grounded. The electrical supply line 702 is connected to the variable DC power supply 703, and the DC current is supplied from the variable DC power supply 703 to the heatable catalytic body 701 through the electrical supply line 702. By supplying the DC current to the heatable catalytic body 701, the heatable catalytic body 701 is heated to a predetermined temperature of, for example, 1400° C. or higher.

Note that a material for the heatable catalytic body 701 is not limited to tungsten, but the other high melting point metal heatable to the temperature as high as 1400° C. or higher, such as tantalum, molybdenum, vanadium, platinum, or thorium, may be used. The high melting point metal used for the heatable catalytic body 701 may not necessarily be a single metal, but may be an alloy.

When the metal film introduced with Si is nitrided, any of the above-described N-containing gases is introduced into the chamber 202 with the heatable catalytic body 701 being heated to the predetermined temperature. When the N-containing gas is brought into contact with the heatable catalytic body 701, the N-containing gas undergoes catalyzed degradation, and is excited to become radicals. The radicals allow the metal film introduced with Si to be nitrided. In the catalytic deposition apparatus 700, for example, because plasma is not used, the metal film introduced with Si can be nitrided with little damage to, for example, an unshown interlayer insulation film, and the like, formed on the semiconductor substrate 101.

The metal film introduced with Si can be nitrided by using the plasma deposition apparatus 500 illustrated in FIG. 6, RLSA microwave plasma deposition apparatus 600 illustrated in FIG. 7, or catalytic deposition apparatus 700 illustrated in FIG. 8.

### Third Embodiment

A third embodiment relates to a specific example of the semiconductor device manufacturing method.

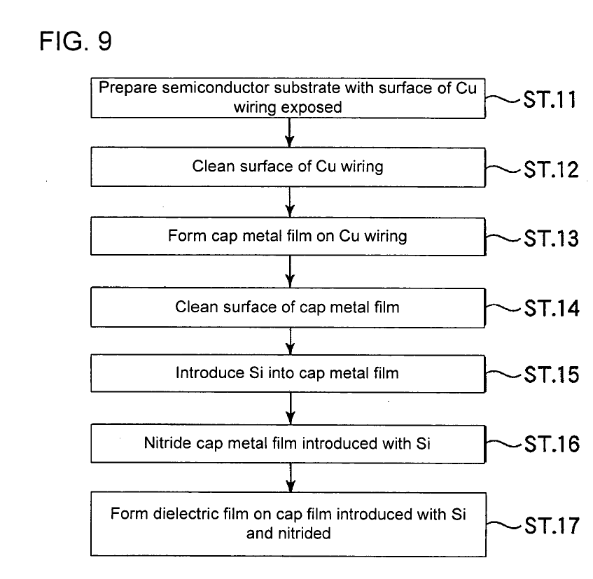

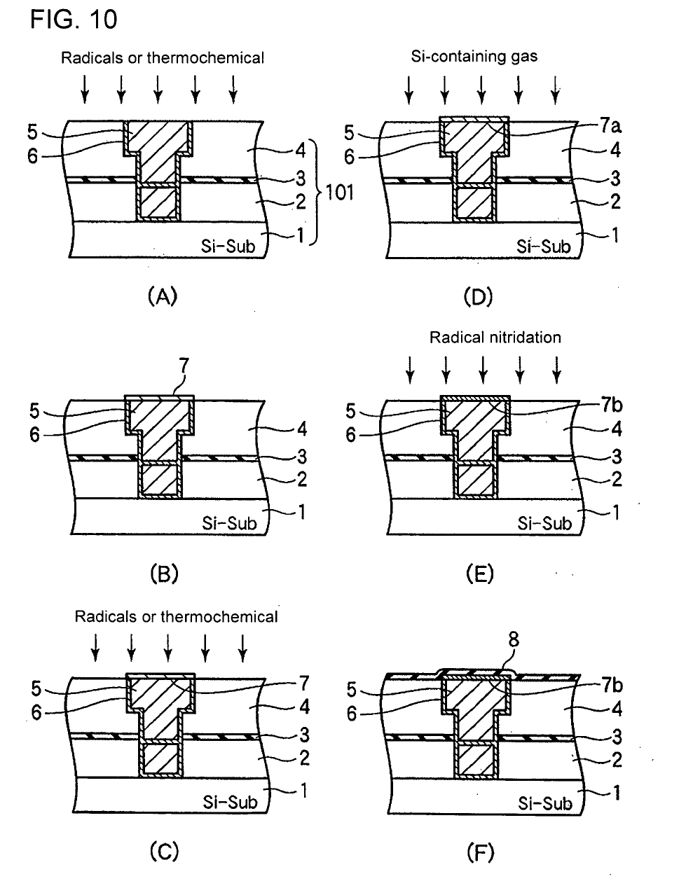

FIG. 9 is a flowchart illustrating an example of a specific flow of a semiconductor device manufacturing method according to the third embodiment of the present invention. FIGS. 10A to 10F are cross sectional views illustrating an example of the semiconductor device manufacturing method according to the third embodiment of the present invention on the basis of respective major manufacturing steps.

The present embodiment is one in which the manufacturing method described in the first embodiment is applied to Cu wiring of a semiconductor device.

First, as indicated by ST.11 in FIG. 9, a semiconductor substrate with a surface of cupper wiring exposed is prepared. As one specific example, as illustrated in FIG. 10A, the semiconductor substrate 101 in a state where a first interlayer insulation film 2, dielectric film 3 functioning as an etching stopper film, and second interlayer insulation film 4 are sequentially formed on a Si substrate (Si-Sub) 1, and Cu wiring 5 is buried in the first and second interlayer insulation films 2 and 4 with a surface thereof being exposed is prepared. Note that the Cu wiring 5 is buried in a wiring trench formed in the first and second interlayer insulation films 2 and 4 with a barrier metal layer 6 being intermediate between the Cu wiring 5 and the interlayer insulation films 2 and 4.

Then, as indicated by ST.12 in FIG. 9, the surface of the Cu wiring 5 is cleaned. As one specific example, as illustrated in FIG. 10A, the exposed surface of the Cu wiring 5 is subjected to cleaning treatment, i.e., reduction treatment in the present embodiment, by a radical method in a vacuum atmosphere or thermochemical method to remove a natural oxide film and the like naturally formed on the surface of the Cu wiring 5.

If the cleaning treatment is applied with the use of the radical method, for example, the RLSA microwave plasma deposition apparatus 600 illustrated in FIG. 7 can be used. In this case, it is only necessary to supply cleaning treatment gas from the gas supply source 211 illustrated in FIG. 7 into the chamber 202. Examples of the cleaning treatment gas for the case of using the radical method include gas containing reducing gas, and examples of the gas containing reducing gas include H₂, N₂, and NH₃ gases, gas mixtures of them, and gas mixtures of the foregoing gases and Ar gas.

The cleaning treatment may be ion-based plasma treatment using, for example, the plasma deposition apparatus 400 illustrated in FIG. 5. Even in this case, it is only necessary to supply the above-described cleaning treatment gas from the gas supply source 211 into the chamber 202. However, rather than the ion-based plasma treatment, radical-based plasma treatment using the microwave plasma deposition apparatus has an advantage of causing less damage to the interlayer insulation film 4.

Also, if the cleaning treatment is applied with the use of the thermochemical method, for example, the thermal deposition apparatus 200 illustrated in FIG. 3 can be used. Even in this case, it is only necessary to supply the cleaning treatment gas from the gas supply source 211 into the chamber 202. Examples of the cleaning treatment gas for the case of using the thermochemical method include reducing gases such as H₂ gas and organic acid. As an example of the organic acid, carboxylic acid such as formic acid, acetic acid, or butyric acid can be used. In particular, anhydrous carboxylic acid such as anhydrous acetic acid is preferable.

Subsequently, as indicated by ST.13 in FIG. 9, the cap metal film is formed on the Cu wiring. As one specific example, as illustrated in FIG. 10B, on the Cu wiring 5 from which the natural oxide film is removed, a cap metal film 7 is formed with being self-aligned with the Cu wiring 5.

The formation of the cap metal film 7 corresponds to ST2 (metal film deposition) illustrated in FIG. 1, and a material for the cap metal film 7 is selected from any of CoW based metal or W. Examples of the CoW based metal include, as described above, CoWB and CoWP. For the deposition of such film, the electroless plating machine 100 illustrated in FIG. 2 or thermal deposition apparatus 200 illustrated in FIG. 3 can be used.

Subsequently, as indicated by ST.14 in FIG. 9, a surface of the cap metal film is cleaned. As one specific example, as illustrated in FIG. 10C, the exposed surface of the cap metal film 7 is subjected to cleaning treatment, i.e., reduction treatment in the present embodiment, by a radical method in a vacuum atmosphere or thermochemical method to remove a natural oxide film and the like naturally formed on the surface of the cap metal film 7. The cleaning treatment of the cap metal film may be one similar to that indicated by ST.12 in FIG. 9 of the present embodiment.

Subsequently, as indicated by ST.15 in FIG. 9, Si is introduced into the cap metal film. As one specific example, as illustrated in FIG. 10D, by exposing to Si-containing gas the cap metal film 7 from which the natural oxide film is removed, Si is introduced into the cap metal film 7 to thereby transform the cap metal film 7 into a Si-containing cap metal film 7a.

The introduction of Si corresponds to ST.3 (Si introduction) illustrated in FIG. 1, and upon the introduction, the thermal deposition apparatus 300 illustrated in FIG. 4 or plasma deposition apparatus 400 illustrated in FIG. 5 can be used.

Subsequently, as indicated by ST.16 in FIG. 9, the cap metal film introduced with Si is nitrided. As one specific example, as illustrated in FIG. 10E, the Si-containing cap metal film 7a is subjected to radical nitridation with the use of radicals to thereby transform the Si-containing cap metal film 7a into, for example, a nitride silicide cap metal film 7b.

The nitriding treatment corresponds to ST.4 (nitridation of metal film introduced with Si) illustrated in FIG. 1. In the present embodiment, a radical nitriding treatment using radical based plasma having lower electron temperature and higher density than those of the typical plasma nitriding treatment is used. Upon the radical nitridation, the RLSA microwave plasma deposition apparatus 600 illustrated in FIG. 7 or catalytic deposition apparatus 700 illustrated in FIG. 8 is used. The nitriding treatment may be ion-based plasma treatment using, for example, the plasma deposition apparatus 500 illustrated in FIG. 6. However, rather than the plasma nitridation, the radical nitridation using the microwave plasma or a catalyst without using plasma has an advantage of causing less damage to the interlayer insulation film 4.

Subsequently, as indicated by ST.17 in FIG. 9, the dielectric film is formed on the cap metal film that is introduced with Si and nitrided. As one specific example, as illustrated in FIG. 10F, a dielectric film 8 is formed on the nitride silicide cap metal film 7b and interlayer insulation film 4. Functional examples of the dielectric film 8 include an etching stopper film and diffusion preventing film. Also, examples of a material for the dielectric film 8 include Si-containing insulator, and the material may be appropriately selected depending on the function of the dielectric film 8. For example, examples of the Si-containing insulator may include SiN, SiCN, and SiC.

The dielectric film 8 can be formed, for example, even if any of the thermal deposition apparatus 200 illustrated in FIG. 3, plasma deposition apparatus 400 illustrated in FIG. 5, RLSA microwave plasma deposition apparatus 600 illustrated in FIG. 7 or catalytic deposition apparatus 700 illustrated in FIG. 8 is used, by replacing the treatment gas from the gas supply source 211 by processing gas capable of depositing the dielectric film 8.

Also, the formation of the dielectric film 8 may be performed as required, and if it is not required, a subsequent interlayer insulation film may be formed on the interlayer insulation film 4 without the formation of the dielectric film 8.

The semiconductor device manufacturing method illustrated in FIG. 1 according to the first embodiment can specifically be applied to the formation of the cap metal film for the Cu wiring 5 as in this third embodiment.

Note that the step of cleaning the surface of the Cu wiring 5 indicated by ST.12 and that of cleaning the surface of the cap metal film 7 indicated by ST.14 may be performed as required, or any one of the steps may only be performed.

### Fourth Embodiment

A fourth embodiment relates to an example of manufacturing apparatus that is used in the example of the basic flow illustrated in FIG. 1 or specific flow illustrated in FIG. 9, and devised to be effectively usable for the basic or specific flow.

(First Manufacturing Apparatus)

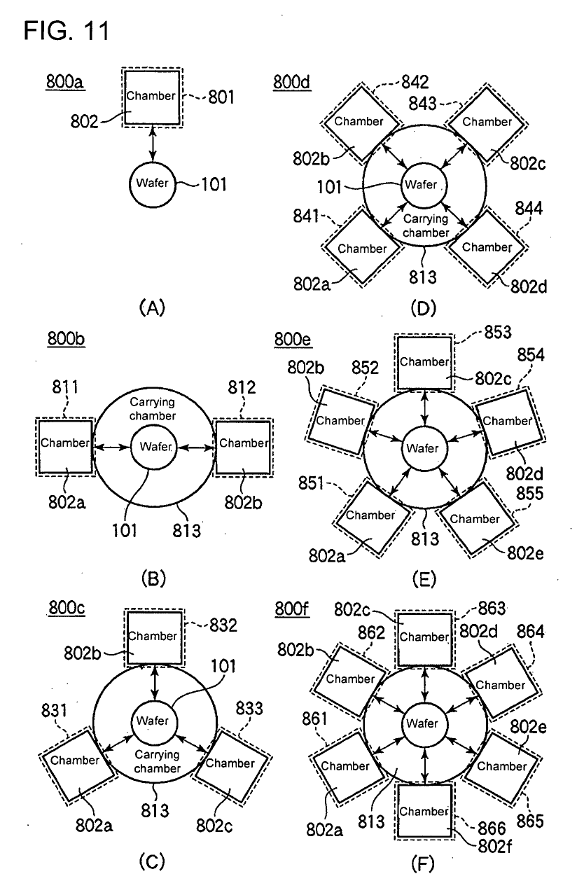

FIG. 11A is a diagram illustrating a schematic configuration of first manufacturing apparatus.

As illustrated in FIG. 11A, the first manufacturing apparatus according to the fourth embodiment of the present invention is one performing the flow described with reference to FIG. 1 or 9 with the use of a single chamber.

As illustrated in FIG. 11A, the first manufacturing apparatus 800a has a processing unit 801 for applying processing to the semiconductor substrate (semiconductor wafer) 101. The processing unit 801 has a single chamber 802, and inside the single chamber 802, the processing according to the flow described with reference to FIG. 1 or 9 is performed.

As a result of the processing, the semiconductor substrate 101 with the Cu or Cu-containing metal film exposed on the surface thereof, which has been carried into the chamber 802, is carried out of the chamber 802 with the metal film being formed on the Cu or Cu-containing metal film.

Some examples of the first manufacturing apparatus 800a are described below.

### First Example of First Manufacturing Apparatus

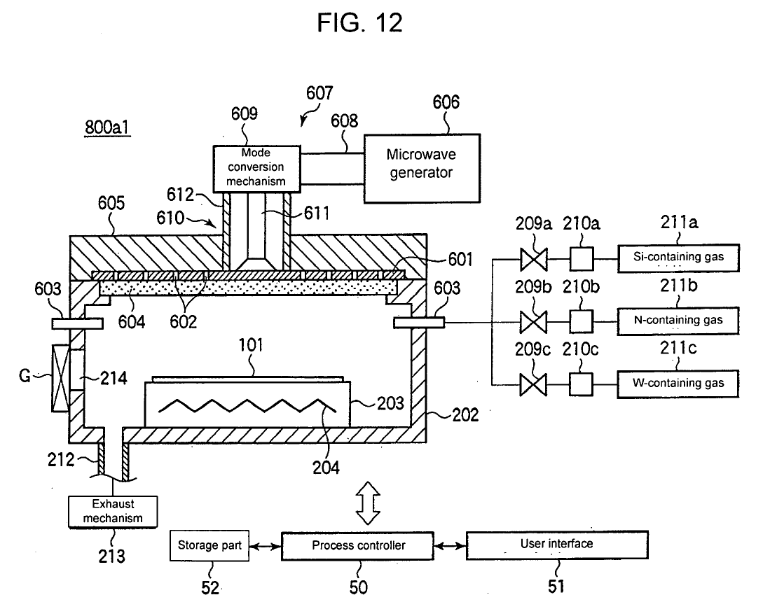

FIG. 12 is a cross-sectional view schematically illustrating a first example of the first manufacturing apparatus.

As illustrated in FIG. 12, manufacturing apparatus 800a1 according to the first example is pursuant to, for example, the RLSA microwave plasma deposition apparatus illustrated in FIG. 7. A particularly different point of the manufacturing apparatus 800a1 from the RLSA plasma deposition apparatus 600 illustrated in FIG. 7 is to comprise gas supply sources 211a to 211c. The gas supply sources 211a to 211c respectively supply Si-containing gas, N-containing gas, and metal film deposition gas (W-containing gas in this example).

The Si-containing gas supplied from the gas supply source 211a is supplied into the chamber 202 through a flow rate controller 210a and opening/closing valve 209a. Similarly, the N-containing and W-containing gases are respectively supplied into the chamber 202 through flow rate controllers 210b and 210c and opening/closing valves 209b and 209c.

A process controller 50 is connected to a user interface 51 and storage part 52. The user interface 51 includes an input means adapted for an operator to input a command to manage the manufacturing apparatus 800a1, for example, a keyboard; a display means adapted to visualize and display a running status to the operator, for example, a display; and the like. The storage part 52 stores a program, so-called process recipe, for performing the processing according to the flow described with reference to FIG. 1 or 9, and adjusting temperature and microwave strength according to a processing condition. The process controller 50 controls the manufacturing apparatus 800a1 according to the process recipe. For example, the process controller 50 opens/closes the opening/closing valves 209a to 209c; controls flow rates through the flow rate controllers 210a to 210c; controls the microwave in the microwave generator 606, mode conversion mechanism 609, or the like: controls temperature of the heater 204; performs exhaust control of the exhaust mechanism 213; performs control of pressure inside the chamber 202 by the exhaust mechanism 213; and performs the other control, according to the process recipe.

The process recipe in this example is stored in a storage medium inside the storage part 52. The storage medium may be a hard disk or semiconductor memory, or alternatively a portable storage medium such as a CD-ROM, DVD, or flash memory. The process recipe is not only stored in the storage medium, but may also be, for example, transmitted from the other device to the process controller 50 through a dedicated line.

The manufacturing apparatus 800a1 according to the first example includes the microwave generator 606 and microwave transmitting mechanism 607, and therefore can perform, for example, the nitriding treatment using the microwave plasma. Also, the heater 204 is buried inside the susceptor 203, and therefore the manufacturing apparatus 800a1 can deposit the metal film on the Cu or Cu-containing alloy film only with the use of heat, or introduce Si into the Cu or Cu-containing alloy film, if the transmission of microwave is stopped.

As described, according to the manufacturing apparatus 800a1 relating to the first example, the deposition of the metal film on the Cu or Cu-containing alloy film; introduction of Si into the Cu or Cu-containing alloy film; and nitridation of the metal film introduced with Si can be performed inside the single chamber 202 (corresponding to the chamber 802 in FIG. 11A).

In addition to this, the manufacturing apparatus 800a1 can continuously perform the above-described processing steps (In-situ processing) with holding the inside of the chamber 202 in vacuum (e.g., 0.13 Pa or higher and 1333 Pa or lower). If the above-described processing steps are continuously performed with the inside of the chamber 202 being held in vacuum, an advantage of suppressing moisture from adsorbing to the interlayer insulation film 4 buried with the Cu or Cu-containing alloy film (see FIGS. 10A to 10F) can be obtained. If the adsorption of moisture to the interlayer insulation film 4 can be suppressed, the Cu or Cu-containing alloy film can be suppressed from being oxidized, so that quality of the Cu or Cu-containing alloy film, for example, the Cu wiring, can be maintained for a long time, and therefore the semiconductor device having high reliability and long life-time can be manufactured.

In particular, the above-described oxidation suppressing effect can be better obtained in the case of a semiconductor device using a low dielectric constant insulation film (Low-k) that is likely to adsorb moisture.

### Second Example of First Manufacturing Apparatus

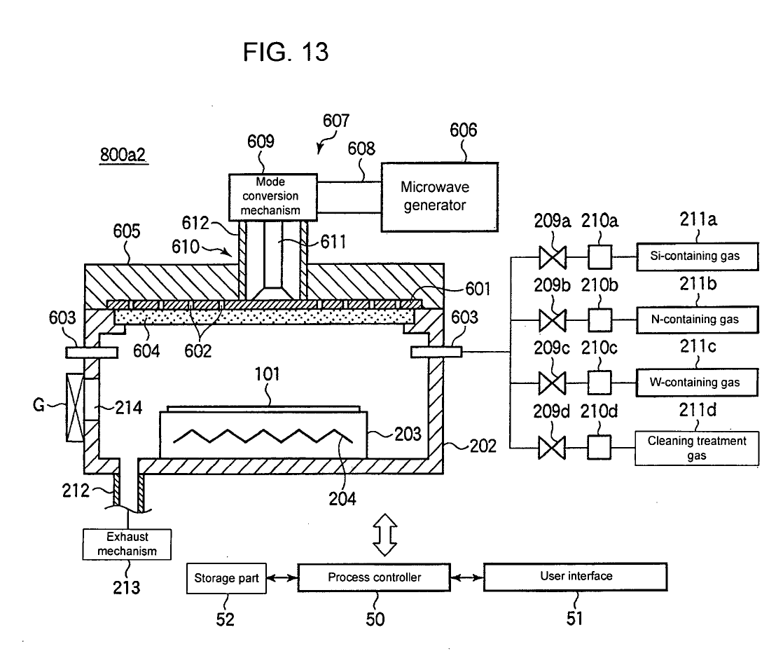

FIG. 13 is a cross-sectional view schematically illustrating a second example of the first manufacturing apparatus.

As illustrated in FIG. 13, manufacturing apparatus 800a2 according to the second example is pursuant to that 800a1 according to the first example; however, it is particularly different that a gas supply source 211d is further provided in addition to the configuration of the manufacturing apparatus 800a1 illustrated in FIG. 12. The gas supply source 211d supplies cleaning treatment gas into the chamber 202 through a flow rate controller 210d and opening/closing valve 209d.

The manufacturing apparatus 800a2 according to the second example can, similarly to that 800a1 according to the first example, perform the deposition of the metal film on the Cu or Cu-containing alloy film; introduction of Si into the Cu or Cu-containing alloy film; and nitridation of the metal film introduced with Si, inside the single chamber 202.

Further, the manufacturing apparatus 800a2 according to the second example is provided with the gas supply source 211d for supplying the cleaning treatment gas, and therefore, in addition to the above-described processing steps, can also particularly perform the cleaning treatment steps described with reference to ST.12 and ST.14 in FIG. 9, for example, the reduction treatment steps of the Cu or Cu-containing alloy film and the metal film, inside the single chamber 202.

Note that the treatment is performed as described above; however, upon the treatment, the reduction treatment of both or any one of the Cu or Cu-containing alloy film and the metal film may be performed.

Even in the manufacturing apparatus 800a2 according to the second example, the processing steps may be continuously performed with the inside of the chamber 202 being held in vacuum (In-situ processing), similarly to the manufacturing apparatus 800a1 according to the first example. Accordingly, even in the manufacturing apparatus 800a2 according to the second example, the same advantage as that in the manufacturing apparatus according to the first example can be obtained.

### Third Example of First Manufacturing Apparatus

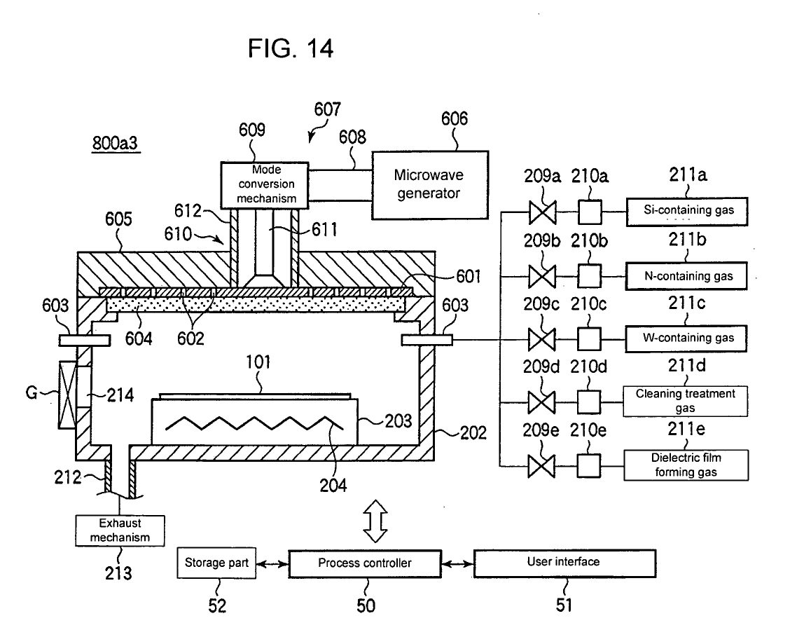

FIG. 14 is a cross-sectional view schematically illustrating a third example of the first manufacturing apparatus.

As illustrated in FIG. 14, manufacturing apparatus 800a3 according to the third example is pursuant to that 800a2 according to the second example; however, it is particularly different that a gas supply source 211e is further provided in addition to the configuration of the manufacturing apparatus 800a2 illustrated in FIG. 13. The gas supply source 211e supplies dielectric film forming gas into the chamber 202 through a flow rate controller 210e and opening/closing valve 209e.

The manufacturing apparatus 800a3 according to the third example can, similarly to that 800a2 according to the second example, perform the deposition of the metal film on the Cu or Cu-containing alloy film; introduction of Si into the Cu or Cu-containing alloy film; nitridation of the metal film introduced with Si; cleaning treatment of the surface of the Cu or Cu-containing alloy film; and cleaning treatment of the surface of the Cu or Cu-containing alloy film, inside the single chamber 202.

Further, the manufacturing apparatus 800a3 according to the third example is provided with the gas supply source 211e for supplying the dielectric film forming gas, and therefore, in addition to the above-described processing steps, can also particularly perform the dielectric film formation processing step described with reference to ST.17 in FIG. 9, inside the single chamber 202.

Note that, in the manufacturing apparatus 800a3 according to the third example, it is only necessary to provide the gas supply source 211d for supplying the cleaning treatment gas, flow rate controller 210d for controlling a flow rate of the cleaning treatment gas, and opening/closing valve 209d for controlling opening/closing of a supply path for the cleaning treatment gas as required.

(Second Manufacturing Apparatus)

FIG. 11B is a diagram illustrating a schematic configuration of second manufacturing apparatus.

As illustrated in FIG. 11B, the second manufacturing apparatus is multi-chamber type manufacturing apparatus performing the flow described with reference to FIG. 1 or 9 with the use of a plurality of chambers.

As illustrated in FIG. 11B, the second manufacturing apparatus 800b includes two processing units 811 and 812. The first processing unit 811 includes a single chamber 802a, and similarly, the second processing unit 812 includes a single chamber 802b. The first and second chambers 802a and 802b are connected to each other through a single carrying chamber 813.

The carrying chamber 813 can hold the inside thereof at a predetermined pressure, for example, in vacuum (e.g., 0.13 Pa or higher and 1333 Pa or lower), similarly to the chambers 802a and 802b.

Further, the inside of the carrying chamber 813, a carrier device (not shown in FIG. 11B) for carrying the semiconductor substrate 101 is provided. The semiconductor substrate (semiconductor wafer) 101 can be carried between the first and second chambers 802a and 802b with the vacuum being held, by a carrying mechanism including the carrying chamber 813 and the above-described carrier device.

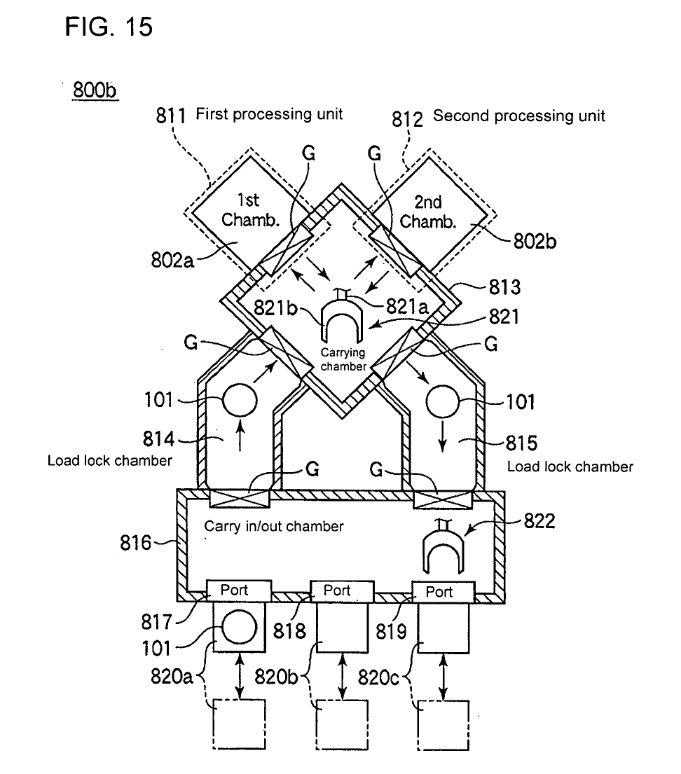

FIG. 15 is a horizontal cross-sectional view illustrating an example of a configuration of the second manufacturing apparatus.

As illustrated in FIG. 15, the first and second processing units 811 and 812 are provided correspondingly to two sides of the carrying chamber 813 of a quadrangular shape, and along the other two sides, load lock chambers 814 and 815 are provided. On sides of the load lock chambers 814 and 815 opposite to the carrying chamber 813, a carry in/out chamber 816 is provided, and on a side of the carry in/out chamber 816 opposite to the load lock chambers 814 and 815, a plurality of ports, i.e., three ports 817 to 819 in this example, are provided. The ports 817 to 819 are fitted with carriers 820a to 820c that can contain a plurality of the semiconductor substrates (semiconductor wafers) 101

The chamber (1st Chamb.) 802a of the first processing unit 811, that (2nd Chamb.) 802b of the second processing unit 812, and load lock chambers 814 and 815 are connected to the respective sides of the carrying chamber 813 through gate valves G. The chambers 802a and 802b and load lock chambers 814 and 815 are communicatively connected to the carrying chamber 813 by opening the corresponding gate valves G, and blocked from the carrying chamber 815 by closing the corresponding gate valves G.

Portions of the load lock chambers 814 and 815, which are connected to the carry in/out chamber 816, are also provided with gate valves G, and the load lock chamber 814 and 815 are communicatively connected to the carry in/out chamber 816 by opening the corresponding gate valves G, and blocked from the carry in/out chamber 816 by closing the corresponding gate valves G.

Inside the carrying chamber 813, a carrier device 821 for carrying in/out the semiconductor substrate 101 to/from the chambers 802a and 802b and load lock chambers 814 and 815 is provided. The carrier device 821 is placed in substantially the center of the carrying chamber 813, and has a rotatable and extendable rotation/extension part 821a, as well as having a blade 821b for holding the semiconductor substrate 101 at an end of the rotation/extension part 821a. The inside of the carrying chamber 813 is adapted to be able to be held at the predetermined pressure, for example, in vacuum, as described above.

The ports 817 to 819 are fitted with the carriers 820a to 820c that contain the semiconductor substrates 101 or nothing. Also, the ports 817 to 819 are provided with shutters (not shown), which are removed when the carriers 820a to 820c are fitted to the ports 817 to 819, whereby the ports 817 to 819 are adapted to be communicatively connected to the carry in/out chamber 816 while preventing outer air from intruding.

Inside the carry in/out chamber 816, a carrier device 822 for carrying in/out the semiconductor substrates 101 contained in the carriers 820a to 820c, and carrying in/out the semiconductor substrates 101 to/from the load lock chambers 814 and 815.

One example of operations of the second manufacturing apparatus is described below.

When any of the carriers 820a to 820c containing the semiconductor substrates 101 is fitted to any of the ports 817 to 819, the unshown shutter is removed to make a communicative connection between the inside of the carrier 820 and that of the carry in/out chamber 816. After the communicative connection has been made, the semiconductor substrate 101 contained in the carrier 820 is carried into the carry in/out chamber 816 with the use of the carrier device 822. This allows the semiconductor substrate 101 to be carried into the second manufacturing apparatus 800b. Subsequently, the gate valve G corresponding to the load lock chamber 814 is opened, and the semiconductor substrate 101 is carried into the load lock chamber 814 with the use of the carrier device 822. After the carriage, the gate valve G is closed to block the inside of the load lock chamber 814 from both of the carry in/out chamber 816 and carrying chamber 813. After the block, pressure inside the load lock chamber 814 is reduced to the predetermined pressure, i.e., vacuum in this example (e.g., 0.13 Pa or higher and 1333 Pa or lower). Along with this, pressure inside the carrying chamber 813 is also reduced to the predetermined pressure, i.e., the same pressure as that inside the load lock chamber 814 in this example (in this example, vacuum within a pressure range of 0.13 Pa or higher and 1333 Pa or lower). After that, the gate valve G is opened, and the semiconductor substrate 101 is carried into the carrying chamber 813. Further, after pressure inside the first chamber 802a has been adjusted to, for example, the same pressure as that inside the carrying chamber 813 (in this example, vacuum within a pressure range of 0.13 Pa or higher and 1333 Pa or lower), the gate valve G is opened to carry the semiconductor substrate 101 from the carrying chamber 813 to the first chamber 802a with the use of the carrier device 821, and predetermined processing is applied to the semiconductor substrate 101 in the first chamber 802a after closing of the gate valve G.

The semiconductor substrate 101 having been subjected to the predetermined processing in the first chamber 802a is carried from the first chamber 802a to the second chamber 802b with the use of the carrier device 821 with the pressure inside the carrying chamber 813 being held at the predetermined pressure, i.e., in vacuum in this example (0.13 Pa or higher and 1333 Pa or lower), and the gate valves G respectively corresponding to the first and second chambers 802a and 802b being opened. After the carriage, the gate valve G corresponding to the second chamber 802b is closed, and predetermined processing is applied to the semiconductor substrate 101 in the second chamber 802b.

The semiconductor substrate 101 having been subjected to the predetermined processing in the second chamber 802b is carried from the second chamber 802b to the carrying chamber 813 with the use of the carrier device 821 with the carrying chamber 813 being held in vacuum and the gate valve G corresponding to the second chamber 802b being opened. After the carriage, pressure inside the load lock chamber 815 is adjusted to the same pressure as that inside the carrying chamber 813. After that, the gate valve G corresponding to the load lock chamber 815 is opened to carry the semiconductor substrate 101 into the load lock chamber 815 with the use of the carrier device 821. After the carriage, the gate valve G is closed to block the inside of the load lock chamber 815 from both of the carrying chamber 813 and carry in/out chamber 816. After the block, the pressure inside the load lock chamber 815 is increased to predetermined pressure, i.e., atmospheric pressure in this example. Subsequently, the gate valve G is opened to carry the semiconductor substrate 101 into the carry in/out chamber 816 with the use of the carrier device 822. After the carriage, the carrier device 822 is used to contain the semiconductor substrate 101 in any of the carriers 820a to 820c fitted to any of the ports 817 to 819. By closing the unshown shutter, and removing the any of the carriers 802a to 802c, which contains the semiconductor substrate 101, from the any of the ports 817 to 819, the semiconductor substrate 101 is carried out of the second manufacturing apparatus 800b.

As described, according to the second manufacturing apparatus 800b, while the plurality of chambers, i.e., the two chambers 802a and 802b in this example, are provided, the semiconductor substrate 101 can be carried between the chambers 802a and 802b with vacuum being held. For this reason, after processing in the chamber 802a, another processing can be performed in the chamber 802b without breaking the vacuum.

Examples of assignments of processing (steps) applied in the first chamber 802a and that (steps) applied in the second chamber 802b are described below.

Table 1 shows assignment examples 1 and 2 of processing (steps) for the case where the basic flow illustrated in FIG. 1 is performed with the use of the second manufacturing apparatus 800b.

TABLE 1

| | Assignment | Assignment |
|---|---|---|
| Process (step) | example 1 | example 2 |
| Metal film deposition | 1st Chamb. | 1st Chamb. |
| Si introduction into metal | 2nd Chamb. | 1st Chamb. |
| film | | |
| Metal film nitridation | 2nd Chamb. | 2nd Chamb. |

### Assignment Example 1

The first chamber (1st Chamb.) 802a used in the assignment example 1 only deposits the metal film on the Cu or Cu-containing metal film, and therefore, for the processing unit 811 provided with the first chamber (1st Chamb.) 802a, for example, the electroless plating machine 100 illustrated in FIG. 2 or thermal deposition apparatus 200 illustrated in FIG. 3 can be used.

The second chamber (2nd Chamb.) 802b introduces Si into the metal film and nitrides the metal film introduced with Si, and therefore, for the processing unit 812 provided with the second chamber (2nd Chamb.) 802b, it is only necessary to use apparatus capable of introducing at least the Si-containing gas and N-containing gas into the second chamber (2nd Chamb.) 802b. For example, apparatus in which the gas supply source 211c, flow rate controller 210c, and opening/closing valve 209c are removed from the manufacturing apparatus 800a1 illustrated in FIG. 12 can be used.

### Assignment Example 2

The first chamber (1st Chamb.) 802a used in the assignment example 2 deposits the metal film on the Cu or Cu-containing metal film and introduces Si into the metal film, and therefore, for the processing unit 811 provided with the first chamber (1st Chamb.) 802a, it is only necessary to use apparatus capable of introducing at least the metal film forming gas and Si-containing gas into the first chamber (1st Chamb.) 802a. For example, apparatus in which the gas supply source 211b, flow rate controller 210b, and opening/closing valve 209b are removed from the manufacturing apparatus illustrated in FIG. 12 can be used.

The second chamber (2nd Chamb.) 802b only nitrides the metal film introduced with Si, and therefore, for the processing unit 812 provided with the second chamber (2nd Chamb.) 802b, for example, the plasma deposition apparatus 500 illustrated in FIG. 6, RLSA microwave plasma deposition apparatus 600 illustrated in FIG. 7, or catalytic deposition apparatus 700 illustrated in FIG. 8 can be used.

Table 2 shows assignment examples 3 to 5 of processing (steps) for the case where the specific flow illustrated in FIG. 9 excluding the dielectric film formation is performed with the use of the second manufacturing apparatus 800b.

TABLE 2

| | Assignment | Assignment | Assignment |
|---|---|---|---|
| Process (step) | example 3 | example 4 | example 5 |
| Metal film | 1st Chamb. | 1st Chamb. | 1st Chamb. |
| deposition | | | |
| Cleaning | 2nd Chamb. | 1st Chamb. | 1st Chamb. |
| Si introduction | 2nd Chamb. | 2nd Chamb. | 1st Chamb. |
| into metal film | | | |
| Metal film | 2nd Chamb. | 2nd Chamb. | 2nd Chamb. |
| nitridation | | | |

### Assignment Example 3

The first chamber (1st Chamb.) 802a used in the assignment example 3 only deposits the metal film on the Cu or Cu-containing metal film, and therefore, for the processing unit 811 provided with the first chamber (1st Chamb.) 802a, for example, the thermal deposition apparatus 200 illustrated in FIG. 3 can be used.

The second chamber (2nd Chamb.) 802b performs the cleaning; introduces Si into the metal film; and nitrides the metal film introduced with Si, and therefore, for the processing unit 812 provided with the second chamber (2nd Chamb.) 802b, it is only necessary to use apparatus capable of introducing at least the cleaning treatment gas, Si-containing gas, and N-containing gas into the second chamber (2nd Chamb.) 802b. For example, apparatus in which the gas supply source 211c, flow rate controller 210c, and opening/closing valve 209c are removed from the manufacturing apparatus 800a2 illustrated in FIG. 13 can be used.

### Assignment Example 4

The first chamber (1st Chamb.) 802a used in the assignment example 4 deposits the metal film on the Cu or Cu-containing metal film, and performs the cleaning, and therefore, for the processing unit 811 provided with the first chamber (1st Chamb.) 802a, it is only necessary to use apparatus capable of introducing at least the metal film forming gas and cleaning treatment gas into the first chamber (1st Chamb.) 802a. For example, apparatus in which the gas supply sources 211a and 211b, flow rate controllers 210a and 210b, and opening/closing valves 209a and 209b are removed from the manufacturing apparatus 800a2 illustrated in FIG. 13 can be used.

The second chamber (2nd Chamb.) 802b introduces Si into the metal film, and nitrides the metal film introduced with Si, and therefore, for the processing unit 812 provided with the second chamber (2nd Chamb.) 802b, it is only necessary to use apparatus capable of introducing at least the Si-containing gas and N-containing gas into the second chamber (2nd Chamb.) 802b. For example, apparatus in which the gas supply sources 211c and 211d, flow rate controllers 210c and 210d, and opening/closing valves 209c and 209d are removed from the manufacturing apparatus 800a2 illustrated in FIG. 13 can be used.

### Assignment Example 5

The first chamber (1st Chamb.) 802a used in the assignment example 5 deposits the metal film on the Cu or Cu-containing metal film; performs the cleaning; and introduces Si into the metal film, and therefore, for the processing unit 811 provided with the first chamber (1st Chamb.) 802a, it is only necessary to use apparatus capable of introducing at least the metal film forming gas, cleaning treatment gas, and Si-containing gas into the first chamber (1st Chamb.) 802a. For example, apparatus in which the gas supply source 211b, flow rate controller 210b, and opening/closing valves 209b are removed from the manufacturing apparatus 800a2 illustrated in FIG. 13 can be used.

The second chamber (2nd Chamb.) 802b only nitrides the metal film introduced with Si, and therefore, for the processing unit 812 provided with the second chamber (2nd Chamb.) 802b, for example, the plasma deposition apparatus 500 illustrated in FIG. 6, RLSA microwave plasma deposition apparatus 600 illustrated in FIG. 7, or catalytic deposition apparatus 700 illustrated in FIG. 8 can be used.

The above-described assignment examples 3 to 5 are ones where continuous processing steps can be performed in a single chamber, and sequential processing steps can be performed in the first and second chambers 802a and 802b. Note that there are some assignment examples where some processing step may arise in the first chamber 802a after returning from the second chamber 802b because the sequential processing steps cannot be completed, and, rather than performing different types of processing steps in different chambers, the number of chambers can be reduced. Such assignment examples 6 to 8 are shown in Table 3.

TABLE 3

| | Assignment | Assignment | Assignment |
|---|---|---|---|
| Process (step) | example 6 | example 7 | example 9 |
| Metal film | 1st Chamb. | 1st Chamb. | 1st Chamb. |
| deposition | | | |
| Cleaning | 2nd Chamb. | 2nd Chamb. | 2nd Chamb. |
| Si introduction | 1st Chamb. | 1st Chamb. | 2nd Chamb. |
| into metal film | | | |
| Metal film | 1st Chamb. | 2nd Chamb. | 1st Chamb. |
| nitridation | | | |

### Assignment Example 6

The first chamber (1st Chamb.) 802a used in the assignment example 6 deposits the metal film on the Cu or Cu-containing metal film; introduces Si into the metal film; and nitrides the metal film introduced with Si. For the processing unit 811 provided with such first chamber (1st Chamb.) 802a, for example, the manufacturing apparatus 800a1 illustrated in FIG. 12 can be used.

The second chamber (2nd Chamb.) 802b only performs the cleaning. For the processing unit 812 provided with such second chamber (2nd Chamb.) 802b, it is only necessary to use apparatus capable of introducing at least the cleaning treatment gas into the second chamber (2nd Chamb.) 802b. For example, apparatus adapted to supply the cleaning treatment gas, instead of the N-containing gas, from the gas supply source 211 of the RLSA microwave plasma deposition apparatus 600 illustrated in FIG. 7, or from the gas supply source 211 of the catalytic deposition apparatus 700 illustrated in FIG. 8 can be used.

### Assignment Example 7

The first chamber (1st Chamb.) 802a used in the assignment example 7 deposits the metal film on the Cu or Cu-containing metal film, and introduces Si into the metal film. For the processing unit 811 provided with such first chamber (1st Chamb.) 802a, it is only necessary to use apparatus capable of introducing at least the metal film forming gas and Si-containing gas into the first chamber (1st Chamb.) 802a. For example, apparatus further comprising, in addition to the configuration of the thermal deposition apparatus 200 illustrated in FIG. 3, a gas supply source for supplying the Si-containing gas, flow rate controller for controlling a flow rate of the Si-containing gas, and opening/closing valve can be used.

The second chamber (2nd Chamb.) 802b performs the cleaning, and nitrides the metal film introduced with Si. For the processing unit 812 provided with such second chamber (2nd Chamb.) 802b, it is only necessary to use apparatus capable of introducing at least the cleaning treatment gas and N-containing gas into the second chamber (2nd Chamb.) 802b. For example, apparatus in which the gas supply sources 211a and 211c, flow rate controllers 210a and 210c, and opening/closing valves 209a and 209c are removed from the manufacturing apparatus 800a2 illustrated in FIG. 13 can be used.

### Assignment Example 8

The first chamber (1st Chamb.) 802a used in the assignment example 8 deposits the metal film on the Cu or Cu-containing metal film, and nitrides the metal film introduced with Si. For the processing unit 811 provided with such first chamber (1st Chamb.) 802a, it is only necessary to use apparatus capable of introducing at least the metal film forming gas and N-containing gas into the first chamber (1st Chamb.) 802a. For example, apparatus in which the gas supply source 211a, flow rate controller 210a, and opening/closing valve 209a are removed from the manufacturing apparatus 800a1 illustrated in FIG. 12 can be used.

The second chamber (2nd Chamb.) 802b performs the cleaning, and introduces Si into the metal film. For the processing unit 812 provided with such second chamber (2nd Chamb.) 802b, it is only necessary to use apparatus capable of introducing at least the cleaning treatment gas and Si-containing gas into the second chamber (2nd Chamb.) 802b. For example, apparatus in which the gas supply sources 211b and 211c, flow rate controllers 210b and 210c, and opening/closing valves 209b and 209c are removed from the manufacturing apparatus 800a2 illustrated in FIG. 13 can be used.

Note that the dielectric film may be formed according to the specific flow illustrated in FIG. 9 after the processing steps have been performed according to the assignment example 3 to 8, with the use of the second manufacturing apparatus 800b. In this case, for example, it is only necessary to adapt the formation of the dielectric film to be performed in the first or second chamber 802a or 802b after the processing steps according to any one of the above-described assignment examples 3 to 8. In such a case, it is only necessary to supply the dielectric film forming gas to the first or second chamber 802a or 802b to form the dielectric film.

Also, the dielectric film may be formed after the processing steps have been performed according to the above-described assignment example 1 or 2, with the use of the second manufacturing apparatus 800b. Even in this case, for example, it is only necessary to adapt the formation of the dielectric film to be performed in the first or second chamber 802a or 802b after the processing steps according to any of the above-described assignment examples 1 and 2. Further, it is only necessary to supply the dielectric film forming gas to the first or second chamber 802a or 802b to form the dielectric film.

(Third Manufacturing Apparatus)

FIG. 11C is a diagram illustrating a schematic configuration of third manufacturing apparatus.

As illustrated in FIG. 11C, a different point of the third manufacturing apparatus 800c from the second manufacturing apparatus 800b illustrated in FIG. 11B is to comprise three processing units 831, 832, and 833. The processing units 831 to 833 respectively have single chambers 802a to 802c. The chambers 802a to 802c are connected to one another through the single carrying chamber 813. The rest is the same as that in the second manufacturing apparatus 800b illustrated in FIG. 11B.

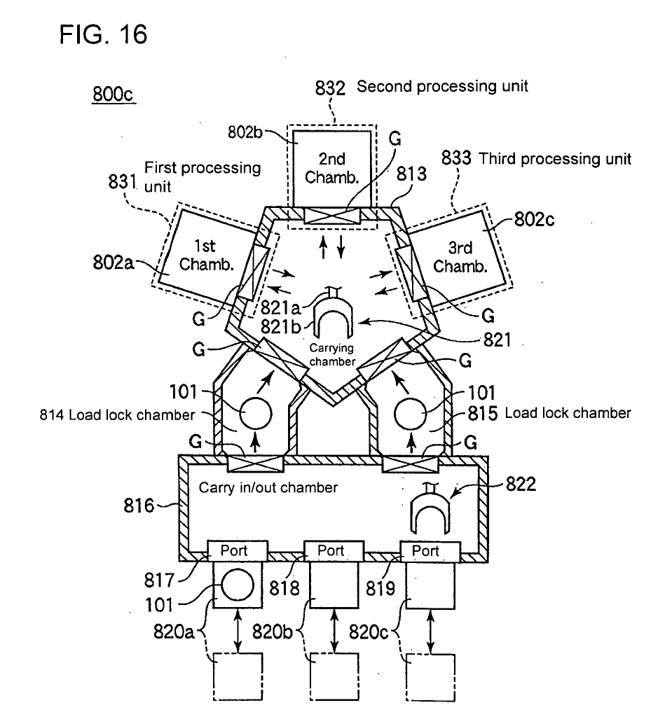

FIG. 16 is a horizontal cross-sectional view illustrating an example of a configuration of the third manufacturing apparatus.

As illustrated in FIG. 16, different points of the third manufacturing apparatus 800c from the second manufacturing apparatus 800b illustrated in FIG. 15 are that the carrying chamber 813 is pentagon-shaped, and the first to third processing units 831 to 833 are provided correspondingly to three sides of the pentagon-shaped carrying chamber 813. The rest is the same as that in the second manufacturing apparatus 800b illustrated in FIG. 15.

Even in the third manufacturing apparatus 800c, while the three chambers 802a to 802c are provided, the semiconductor substrate 101 can be carried between the chambers 802a and 802b, the chambers 802b and 802c, or the chambers 802a and 802c with vacuum being held. Accordingly, even after processing in any of the chambers 802a to 802c, another processing can be performed in the other chamber without breaking the vacuum.

Assignment examples of processing (steps) respectively applied in the first to third chambers 802a to 802c are described below.

Table 4 shows an assignment example 1 of processing (steps) for the case where the basic flow illustrated in FIG. 1 is performed with the use of the third manufacturing apparatus 800c.

TABLE 4

| Process (step) | Assignment example 1 |
|---|---|
| Metal film deposition | 1st Chamb. |
| Si introduction into metal film | 2nd Chamb. |
| Metal film nitridation | 3rd Chamb. |

### Assignment Example 1

An assignment example 1 is one where all of the processing steps according to the flow illustrated in FIG. 1 are respectively performed in the different chambers.

In the assignment example 1, all of the processing steps are respectively performed in the different chambers, and therefore the first chamber (1st Chamb.) 802a used in the assignment example 1 only deposits the metal film on the Cu or Cu-containing metal film. For the processing unit 831 provided with such first chamber (1st Chamb.) 802a, for example, the thermal deposition apparatus 200 illustrated in FIG. 3 can be used.

Similarly, the second chamber (2nd Chamb.) 802b only introduces Si into the metal film. For the processing unit 832 provided with such second chamber (2nd Chamb.) 802b, the thermal deposition apparatus 300 illustrated in FIG. 4, or plasma deposition apparatus 400 illustrated in FIG. 5 can be used.

Similarly, the third chamber (3rd Chamb.) 802c only nitrides the metal film introduced with Si. For the processing unit 833 provided with such third chamber (3rd Chamb.) 802c, the plasma deposition apparatus 500 illustrated in FIG. 6, RLSA microwave plasma deposition apparatus 600 illustrated in FIG. 7, or catalytic deposition apparatus 700 illustrated in FIG. 8 can be used.

Table 5 shows assignment examples 2 to 4 of processing (steps) for the case where the specific flow illustrated in FIG. 9 excluding the dielectric film formation is performed with the use of the third manufacturing apparatus 800c.

TABLE 5

| | Assignment | Assignment | Assignment |
|---|---|---|---|
| Process (step) | example 2 | example 3 | example 4 |
| Metal film | 1st Chamb. | 1st Chamb. | 1st Chamb. |
| deposition | | | |
| Cleaning | 2nd Chamb. | 1st Chamb. | 2nd Chamb. |
| Si introduction | 3rd Chamb. | 2nd Chamb. | 2nd Chamb. |
| into metal film | | | |
| Metal film | 3rd Chamb. | 3rd Chamb. | 3rd Chamb. |
| nitridation | | | |

### Assignment Example 2

The first chamber (1st Chamb.) 802a used in the assignment example 2 only deposits the metal film on the Cu or Cu-containing metal film. Accordingly, for the processing unit 831 provided with the first chamber (1st Chamb.) 802a, for example, the thermal deposition apparatus 200 illustrated in FIG. 3 can be used.

The second chamber (2nd Chamb.) 802b only performs the cleaning. Accordingly, for the processing unit 832 provided with the second chamber (2nd Chamb.) 802b, for example, apparatus adapted to supply the cleaning treatment gas, instead of the N-containing gas, from the gas supply source 211 of the RLSA microwave plasma deposition apparatus 600 illustrated in FIG. 7, or from the gas supply source 211 of the catalytic deposition apparatus 700 illustrated in FIG. 8 can be used.

The third chamber (3rd Chamb.) 802c introduces Si into the metal film, and nitrides the metal film introduced with Si. Accordingly, for the processing unit 833 provided with the third chamber (3rd Chamb.) 802c, it is only necessary to use apparatus capable of introducing at least the Si-containing gas and N-containing gas into the third chamber (3rd Chamb.) 802c. For example, apparatus in which the gas supply source 211c, flow rate controller 210c, and opening/closing valve 209c are removed from the manufacturing apparatus 800a1 illustrated in FIG. 12 can be used.

### Assignment Example 3

The first chamber (1st Chamb.) 802a used in the assignment example 3 deposits the metal film on the Cu or Cu-containing metal film, and performs the cleaning. Accordingly, for the processing unit 831 provided with the first chamber (1st Chamb.) 802a, it is only necessary to use apparatus capable of introducing at least the metal film forming gas and cleaning treatment gas into the first chamber (1st Chamb.) 802a. For example, apparatus in which the gas supply sources 211a and 211b, flow rate controllers 210a and 210b, and opening/closing valves 209a and 209b are removed from the manufacturing apparatus 800a2 illustrated in FIG. 13 can be used.

The second chamber (2nd Chamb.) 802b only introduces Si into the metal film. Accordingly, for the processing unit 832 provided with the second chamber (2nd Chamb.) 802b, the thermal deposition apparatus 300 illustrated in FIG. 4 or plasma deposition apparatus 400 illustrated in FIG. 5 can be used.

The third chamber (3rd Chamb.) 802c only nitrides the metal film introduced with Si. Accordingly, for the processing unit 833 provided with the third chamber (3rd Chamb.) 802c, the plasma deposition apparatus 500 illustrated in FIG. 6, RLSA microwave plasma deposition apparatus 600 illustrated in FIG. 7, or catalytic deposition apparatus 700 illustrated in FIG. 8 can be used.

### Assignment Example 4

The first chamber (1st Chamb.) 802a used in the assignment example 4 only deposits the metal film on the Cu or Cu-containing metal film. Accordingly, for the processing unit 831 provided with the first chamber (1st Chamb.) 802a, for example, the thermal deposition apparatus 200 illustrated in FIG. 3 can be used.

The second chamber (2nd Chamb.) 802b performs the cleaning, and introduces Si into the metal film. For the processing unit 832 provided with the second chamber (2nd Chamb.) 802b, it is only necessary to use apparatus capable of introducing at least the cleaning treatment gas and Si-containing gas into the second chamber (2nd Chamb.) 802b. For example, apparatus in which the gas supply sources 211b and 211c, flow rate controllers 210b and 210c, and opening/closing valves 209b and 209c are removed from the manufacturing apparatus 800a2 illustrated in FIG. 13 can be used.

The third chamber (3rd Chamb.) 802c only nitrides the metal film introduced with Si. Accordingly, for the processing unit 833 provided with the third chamber (3rd Chamb.) 802c, the plasma deposition apparatus 500 illustrated in FIG. 6, RLSA microwave plasma deposition apparatus 600 illustrated in FIG. 7, or catalytic deposition apparatus 700 illustrated in FIG. 8 can be used.

The above-described assignment examples 2 to 4 are ones where continuous processing steps can be performed in a single chamber, and sequential processing steps can be performed in the first to third chambers 802a to 802c. Note that there are some assignment examples where some processing step may arise in the first chamber 802a after returning from the third chamber 802c, in the second chamber 802b after returning from the third chamber 802c, or in the first chamber 802a after returning from the second chamber 802b because the sequential processing steps cannot be completed, and, rather than respectively performing different types of processing steps in different chambers, the number of chambers can be reduced. Such assignment examples 5 to 7 are shown in Table 6.

TABLE 6

| | Assignment | Assignment | Assignment |
|---|---|---|---|
| Process (step) | example 5 | example 6 | example 7 |
| Metal film | 1st Chamb. | 1st Chamb. | 1st Chamb. |
| deposition | | | |
| Cleaning | 2nd Chamb. | 2nd Chamb. | 2nd Chamb. |
| Si introduction | 3rd Chamb. | 3rd Chamb. | 1st Chamb. |
| into metal film | | | |
| Metal film | 1st Chamb. | 2nd Chamb. | 3rd Chamb. |
| nitridation | | | |

### Assignment Example 5

The first chamber (1st Chamb.) 802a used in the assignment example 5 deposits the metal film on the Cu or Cu-containing metal film, and nitrides the metal film introduced with Si. For the processing unit 831 provided with such first chamber (1st Chamb.) 802a, it is only necessary to use apparatus capable of introducing at least the metal film forming gas and N-containing gas into the first chamber (1st Chamb.) 802a. For example, apparatus in which the gas supply source 211a, flow rate controller 210a, and opening/closing valve 209a are removed from the manufacturing apparatus 800a1 illustrated in FIG. 12 can be used.

The second chamber (2nd Chamb.) 802b only performs the cleaning. Accordingly, for the processing unit 832 provided with the second chamber (2nd Chamb.) 802b, for example, apparatus adapted to supply the cleaning treatment gas, instead of the N-containing gas, from the gas supply source 211 of the RLSA microwave plasma deposition apparatus 600 illustrated in FIG. 7, or from the gas supply source 211 of the catalytic deposition apparatus 700 illustrated in FIG. 8 can be used.

The third chamber (3rd Chamb.) 802c only introduces Si into the metal film. Accordingly, for the processing unit 833 provided with the third chamber (3rd Chamb.) 802c, the thermal deposition apparatus 300 illustrated in FIG. 4, or plasma deposition apparatus 400 illustrated in FIG. 5 can be used.

### Assignment Example 6

The first chamber (1st Chamb.) 802a used in the assignment example 6 only deposits the metal film on the Cu or Cu-containing metal film. Accordingly, for the processing unit 831 provided with the first chamber (1st Chamb.) 802a, for example, the thermal deposition apparatus 200 illustrated in FIG. 3 can be used.

Also, the second chamber (2nd Chamb.) 802b performs the cleaning, and nitrides the metal film introduced with Si. For the processing unit 832 provided with such second chamber (2nd Chamb.) 802b, it is only necessary to use apparatus capable of introducing at least the cleaning treatment gas and N-containing gas into the second chamber (2nd Chamb.) 802b. For example, apparatus in which the gas supply sources 211a and 211c, flow rate controllers 210a and 210c, and opening/closing valves 209a and 209c are removed from the manufacturing apparatus 800a2 illustrated in FIG. 13 can be used.

The third chamber (3rd Chamb.) 802c only introduces Si into the metal film. Accordingly, for the processing unit 833 provided with the third chamber (3rd Chamb.) 802c, the thermal deposition apparatus 300 illustrated in FIG. 4, or plasma deposition apparatus 400 illustrated in FIG. 5 can be used.

### Assignment Example 7

The first chamber (1st Chamb.) 802a used in the assignment example 7 deposits the metal film on the Cu or Cu-containing metal film, and introduces Si into the metal film. For the processing unit 831 provided with such first chamber (1st Chamb.) 802a, it is only necessary to use apparatus capable of introducing at least the metal film forming gas and Si-containing gas into the first chamber (1st Chamb.) 802a. For example, apparatus further comprising, in addition to the configuration of the thermal deposition apparatus 200 illustrated in FIG. 3, a gas supply source for supplying the Si-containing gas, flow rate controller for controlling a flow rate of the Si-containing gas, and opening/closing valve can be used.

The second chamber (2nd Chamb.) 802b only performs the cleaning. Accordingly, for the processing unit 832 provided with the second chamber (2nd Chamb.) 802b, apparatus adapted to supply the cleaning treatment gas, instead of the N-containing gas, from the gas supply source 211 of the RLSA microwave plasma deposition apparatus 600 illustrated in FIG. 7, or from the gas supply source 211 of the catalytic deposition apparatus 700 illustrated in FIG. 8 can be used.

The third chamber (3rd Chamb.) 802c only nitrides the metal film introduced with Si. Accordingly, for the processing unit 833 provided with the third chamber (3rd Chamb.) 802c, the plasma deposition apparatus 500 illustrated in FIG. 6, RLSA microwave plasma deposition apparatus 600 illustrated in FIG. 7, or catalytic deposition apparatus 700 illustrated in FIG. 8 can be used.

Note that the dielectric film may be formed according to the specific flow illustrated in FIG. 9 after the processing steps have been performed according to the assignment example 2 to 7, with the use of the third manufacturing apparatus 800c. In this case, for example, it is only necessary to adapt the formation of the dielectric film to be performed in the first, second, or third chamber 802a, 802b, or 802c after the processing steps according to any one of the above-described assignment examples 2 to 7. In such a case, it is only necessary to supply the dielectric film forming gas to the first, second, or third chamber 802a, 802b, or 802c to form the dielectric film.

Also, the dielectric film may be formed after the processing steps have been performed according to the above-described assignment example 1, with the use of the third manufacturing apparatus 800c. Even in this case, for example, it is only necessary to adapt the formation of the dielectric film to be performed in any one of the first to third chambers 802a to 802c after the processing steps according to the above-described assignment example 1. Further, it is only necessary to supply the dielectric film forming gas into the first to third chamber 802a to 802c to form the dielectric film.

(Fourth Manufacturing Apparatus)

FIG. 11D is a diagram illustrating a schematic configuration of fourth manufacturing apparatus.

As illustrated in FIG. 11D, a different point of the fourth manufacturing apparatus 800d from the third manufacturing apparatus 800c illustrated in FIG. 11C is to comprise four processing units 841, 842, 843, and 844. The processing units 841 to 844 respectively have single chambers 802a to 802d. The chambers 802a to 802d are connected to one another through the single carrying chamber 813. The rest is the same as that in the third manufacturing apparatus 800c illustrated in FIG. 1C.

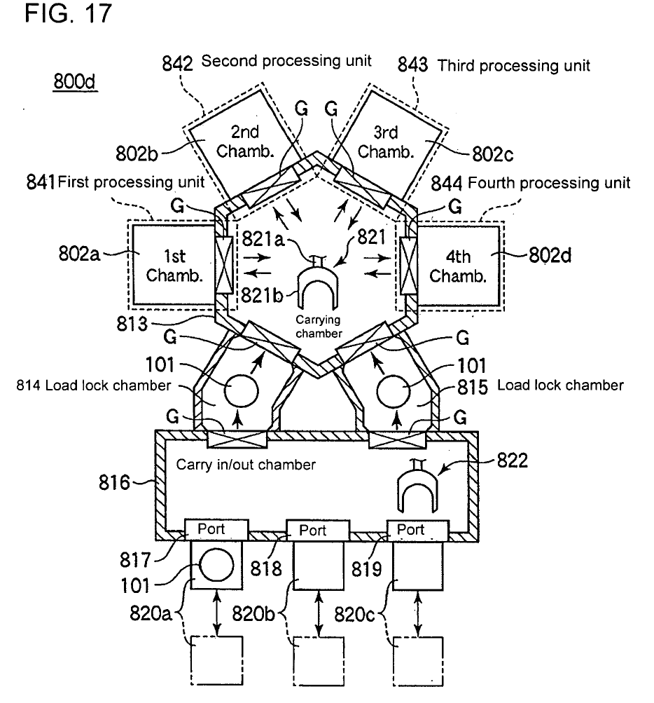

FIG. 17 is a horizontal cross-sectional view illustrating an example of a configuration of the fourth manufacturing apparatus.

As illustrated in FIG. 17, different points of the fourth manufacturing apparatus 800d from the third manufacturing apparatus 800c illustrated in FIG. 16 are that the carrying chamber 813 is hexagon-shaped, and the first to fourth processing units 841 to 844 are provided correspondingly to four sides of the hexagon-shaped carrying chamber 813. The rest is the same as that in the third manufacturing apparatus 800c illustrated in FIG. 16.

Even in the fourth manufacturing apparatus 800d, the semiconductor substrate 101 can be carried between any two of the chambers 802a to 802d with vacuum being held. Accordingly, even after processing in any of the chambers 802a to 802d, another processing can be performed in the other chamber without breaking the vacuum.

An assignment example of processing (steps) respectively applied in the first to fourth chambers 802a to 802d is shown in Table 7.

TABLE 7

| Process (step) | Assignment example 1 |
|---|---|
| Metal film deposition | 1st Chamb. |
| Cleaning | 2nd Chamb. |
| Si introduction into metal film | 3rd Chamb. |
| Metal film nitridation | 4th Chamb. |

### Assignment Example 1

In the assignment example 1, all of the processing steps are respectively performed in the different chambers, and therefore the first chamber (1st Chamb.) 802a used in the assignment example 1 only deposits the metal film on the Cu or Cu-containing metal film. For the processing unit 841 provided with such first chamber (1st Chamb.) 802a, for example, the thermal deposition apparatus 200 illustrated in FIG. 3 can be used.

The second chamber (2nd Chamb.) 802b only performs the cleaning. Accordingly, for the processing unit 842 provided with the second chamber (2nd Chamb.) 802b, it is only necessary to use apparatus capable of introducing at least the cleaning treatment gas into the second chamber (2nd Chamb.) 802b. For example, apparatus adapted to supply the cleaning treatment gas, instead of the N-containing gas, from the gas supply source 211 of the RLSA microwave plasma deposition apparatus 600 illustrated in FIG. 7, or from the gas supply source 211 of the catalytic deposition apparatus 700 illustrated in FIG. 8 can be used.

Similarly, the third chamber (3rd Chamb.) 802c only introduces Si into the metal film. For the processing unit 843 provided with such third chamber (3rd Chamb.) 802c, the thermal deposition apparatus 300 illustrated in FIG. 4, or plasma deposition apparatus 400 illustrated in FIG. 5 can be used.

Similarly, the fourth chamber (4th Chamb.) 802d only nitrides the metal film introduced with Si. For the processing unit 844 provided with such fourth chamber (4th Chamb.) 802d, the plasma deposition apparatus 500 illustrated in FIG. 6, RLSA microwave plasma deposition apparatus 600 illustrated in FIG. 7, or catalytic deposition apparatus 700 illustrated in FIG. 8 can be used.

Because the fourth manufacturing apparatus 800d includes the four chambers 802a to 802d, the processing steps for the case where the flow illustrated in FIG. 9 excluding the dielectric film formation is performed can be respectively performed in the different chambers without breaking vacuum, as shown in Table 7.

Also, the dielectric film may be formed according to the flow illustrated in FIG. 9. In this case, it is only necessary to appropriately set whether the formation of the dielectric film is performed in the first chamber (1st Chamb.) 802a, second chamber (2nd Chamb.) 802b, third chamber (3rd Chamb.) 802c, or fourth chamber (4th Chamb.) 802d after the processing steps according to the assignment example 1. Further, it is only necessary to configure any of the first to fourth chambers 802a to 802d, where the dielectric film is formed, to be supplied with the dielectric film forming gas so as to be able to form the dielectric film.

Note that the fourth manufacturing apparatus 800d includes the four chambers 802a to 802d, and therefore can be advantageously used for a semiconductor device manufacturing method using a flow having four or more steps, for example, as the flow described with reference to FIG. 9.

However, the fourth manufacturing apparatus 800d can be used even in the case of a flow having less than four steps. For example, a semiconductor device may have layers of wiring, and processing applied may be changed for each of the layers of wiring. If processing applied is changed for each of the layers of wiring, wiring formed by applying the flow described with reference to FIG. 1, and that formed by applying the flow described with reference to FIG. 9 may be mixed in one semiconductor device.

Even in such a case, if any one of the four chambers 802a to 802d is not used, a semiconductor device according to the flow described with reference to FIG. 1 can be manufactured, whereas if all of the four chambers 802a to 802d are used, a semiconductor device according to the flow described with reference to FIG. 9 can be manufactured. Accordingly, the fourth manufacturing apparatus 800d comprising the four chambers 802a to 802d can be used even in the case of the flow having less than four steps.

(Fifth Manufacturing Apparatus)

FIG. 11E is a diagram illustrating a schematic configuration of fifth manufacturing apparatus.

As illustrated in FIG. 11E, a different point of the fifth manufacturing apparatus 800e from the fourth manufacturing apparatus 800d illustrated in FIG. 11D is to comprise five processing units 851, 852, 853, 854 and 855. The processing units 851 to 855 respectively have single chambers 802a to 802e. The chambers 802a to 802e are connected to one another through the single carrying chamber 813. The rest is the same as that in the fourth manufacturing apparatus 800d illustrated in FIG. 11D.

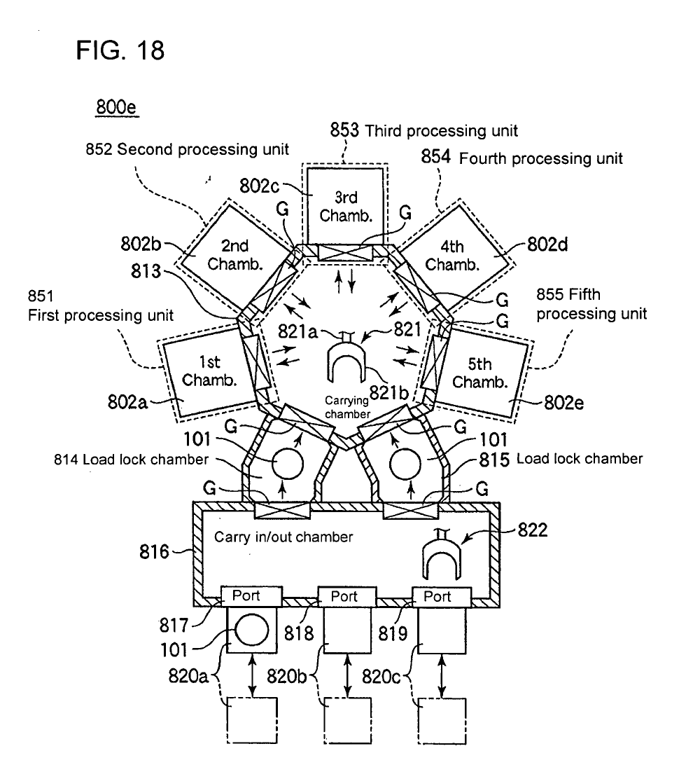

FIG. 18 is a horizontal cross-sectional view illustrating an example of a configuration of the fifth manufacturing apparatus.

As illustrated in FIG. 18, different points of the fifth manufacturing apparatus 800e from the fourth manufacturing apparatus 800d illustrated in FIG. 17 are that the carrying chamber 813 is heptagon-shaped, and the first to fifth processing units 851 to 855 are provided correspondingly to five sides of the heptagon-shaped carrying chamber 813. The rest is the same as that in the fourth manufacturing apparatus 800d illustrated in FIG. 17.

Even in the fifth manufacturing apparatus 800e, because a carrying mechanism including: the single carrying chamber 813 that is connected to each of the chambers 802a to 802e and can hold the inside thereof in vacuum; and the carrier device 821 provided inside the carrying chamber 813 is provided, the semiconductor substrate 101 can be carried between any two of the chambers 802a to 802e with the vacuum being held. Accordingly, even after processing in any of the chambers 802a to 802e, another processing can be performed in the other chamber without breaking the vacuum.

An assignment example of processing (steps) respectively applied in the first to fifth chambers 802a to 802e is shown in Table 8.

TABLE 8

| Process (step) | Assignment example 1 |
|---|---|
| Metal film deposition | 1st Chamb. |
| Cleaning | 2nd Chamb. |
| Si introduction into metal film | 3rd Chamb. |
| Metal film nitridation | 4th Chamb. |
| Dielectric film formation | 5th Chamb. |

### Assignment Example 1

In the assignment example 1 for the fifth manufacturing apparatus 800e, for the processing units 851 to 854 respectively provided with the first to fourth chambers 802a to 802d, the same types of apparatus as those used for the processing units 841 to 844 described in the assignment example 1 for the above-described fourth manufacturing apparatus 800d can be used.

For the processing unit provided with the fifth chamber (5th Chamb.) 855, apparatus capable of introducing at least the dielectric film forming gas into the fifth chamber (5th Chamb.) 855 can be used.

The fifth manufacturing apparatus 800e includes the five chambers 802a to 802e, and therefore can perform all of the processing steps according to the flow illustrated in FIG. 9 in the different chambers, respectively, without breaking vacuum, as shown in Table 8.

Note that the fifth manufacturing apparatus 800e can also be used even in the case of a flow having less than five steps, similarly to the fourth manufacturing apparatus 800d.

(Sixth Manufacturing Apparatus)

FIG. 11F is a diagram illustrating a schematic configuration of sixth manufacturing apparatus.

As illustrated in FIG. 11F, a different point of the sixth manufacturing apparatus 800f from the fifth manufacturing apparatus 800e illustrated in FIG. 11E is to include six processing units 861, 862, 863, 864, 865 and 866. The processing units 861 to 866 respectively have single chambers 802a to 802f. The chambers 802a to 802f are connected to one another through the single carrying chamber 813. The rest is the same as that in the fifth manufacturing apparatus 800e illustrated in FIG. 1E.

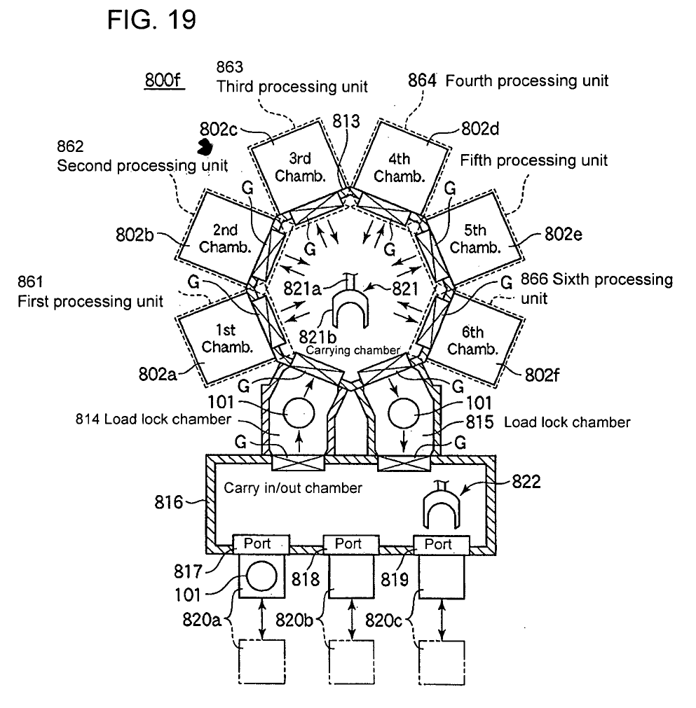

FIG. 19 is a horizontal cross-sectional view illustrating an example of a configuration of the sixth manufacturing apparatus.

As illustrated in FIG. 19, different points of the sixth manufacturing apparatus 800f from the fifth manufacturing apparatus 800e illustrated in FIG. 18 are that the carrying chamber 813 is octagon-shaped, and the first to sixth processing units 861 to 866 are provided correspondingly to six sides of the octagon-shaped carrying chamber 813. The rest is the same as that in the fifth manufacturing apparatus 800e illustrated in FIG. 18.

Even in the sixth manufacturing apparatus 800f, because a carrying mechanism including: the single carrying chamber 813 that is connected to each of the chambers 802a to 802f and can hold the inside thereof in vacuum; and the carrier device 821 provided inside the carrying chamber 813 is provided, the semiconductor substrate 101 can be carried between any two of the chambers 802a to 802f with the vacuum being held. Accordingly, even after processing in any of the chambers 802a to 802f, another processing can be performed in the other chamber without breaking the vacuum.

An assignment example of processing (steps) respectively applied in the first to sixth chambers 802a to 802f is shown in Table 9.

TABLE 9

| | Assignment |
|---|---|
| Process (step) | example 1 |
| Cleaning of Cu or Cu-containing metal film | 1st Chamb. |
| Metal film deposition | 2nd Chamb. |
| Cleaning of metal film | 3rd Chamb. |
| Si introduction into metal film | 4th Chamb. |
| Metal film nitridation | 5th Chamb. |
| Dielectric film formation | 6th Chamb. |

### Assignment Example 1

In the assignment example 1 for the sixth manufacturing apparatus 800f, for the processing units 861 to 866 respectively provided with the first to sixth chambers 802a to 802f, the same types of apparatus as those used for the processing units 851 to 855 described in the assignment example 1 for the above-described fifth manufacturing apparatus 800e can be used.

The sixth manufacturing apparatus 800f includes the six chambers 802a to 802f, and therefore can perform all of the processing steps according to the flow illustrated in FIG. 9 in the different chambers, respectively, without breaking vacuum, as shown in Table 9.

In addition to this, because the sixth manufacturing apparatus 800f can perform the cleaning of the Cu or Cu-containing metal film and that of the metal film in the different chambers, respectively, it does not have to perform processing for returning to a previously-used chamber to perform the cleaning of the metal film, and therefore can further obtain an advantage of, for example, achieving better throughput as compared with the fifth manufacturing apparatus 800e.

As above, the present invention has been described according to the first to fourth embodiments; however, the present invention is not limited to the above-described first to fourth embodiments, but may be variously modified.

For example, in the description of the first manufacturing apparatus according to the fourth embodiment, there has been exemplified the apparatus that continuously performs inside the single chamber the processing steps from the metal film formation to the nitridation of the metal film introduced with Si, from the cleaning treatment to the nitridation of the metal film introduced with Si, or from the cleaning treatment to the dielectric film formation, on the basis of the RLSA microwave plasma deposition apparatus illustrated in FIG. 7. In such apparatus continuously performing the processing steps, as the base apparatus, for example, the catalytic deposition apparatus illustrated in FIG. 8 may be adapted to be used.

Also, in the description of any of the first to sixth manufacturing apparatus, there has been exemplified the apparatus capable of continuously or separately performing the different processing steps inside the single chamber; however, the apparatus capable of continuously or separately performing the different processing steps inside the single chamber is not limited to any of the fist to sixth manufacturing apparatus.

For example, if the metal film is adapted to be deposited on the basis of the electroless plating method illustrated in FIG. 2, the chamber for performing the electroless plating may be configured separately from another chamber for performing vacuum processing, and the semiconductor substrate may be adapted to be carried between the two chambers through a load lock device.

Besides, the above-described first to fourth embodiments may be variously modified without departing from the scope of the present invention.

What is claimed is:

1. A semiconductor device manufacturing method comprising the steps of:
preparing a semiconductor substrate with a copper or a copper-containing metal film exposed on a surface;
depositing a metal film consisting essentially of either cobalt-tungsten based metal (CoW) or tungsten (W) on said copper or said copper-containing metal film;
introducing Si into said metal film; and
nitriding said metal film introduced with Si.

2. The semiconductor device manufacturing method according to claim 1, wherein
said cobalt-tungsten based metal is cobalt-tungsten-boron (CoWB) or
cobalt-tungsten-phosphorus (CoWP).

3. The semiconductor device manufacturing method according to claim 2, wherein
said metal film is formed with use of an electroless plating method.

4. The semiconductor device manufacturing method according to claim 1, wherein
said metal film is formed with use of a chemical vapor deposition method in case when said metal film consists essentially of W.

5. The semiconductor device manufacturing method according to claim 1, wherein
said step of introducing Si is a step of exposing said metal film to silicon-containing gas to introduce said Si into the metal film.

6. The semiconductor device manufacturing method according to claim 1, wherein
said step of nitriding said metal film introduced with Si uses radicals formed by bringing treatment gas into a plasma state with use of a microwave.

7. The semiconductor device manufacturing method according to claim 1, wherein
said step of nitriding said metal film introduced with Si uses radicals formed by bringing treatment gas into contact with a catalyst.

8. The semiconductor device manufacturing method according to claim 4, wherein
said step of depositing a metal film and said step of nitriding said metal film introduced with Si are performed in one and same chamber.

9. The semiconductor device manufacturing method according to claim 4, wherein
said step of depositing a metal film and said step of introducing Si into said metal film are performed in a first chamber; and
said step of nitriding said metal film introduced with Si is performed in a second chamber.

10. The semiconductor device manufacturing method according to claim 9, wherein
said semiconductor substrate is carried with vacuum being held between said first chamber and said second chamber.

11. The semiconductor device manufacturing method according to claim 1, wherein
said step of depositing a metal film is performed in a first chamber; and
said step of introducing Si into said metal film and said step of nitriding said metal film introduced with Si are performed in a second chamber.

12. The semiconductor device manufacturing method according to claim 11, further comprising the steps of:
performing reduction treatment of a surface of said metal film prior to said steps of introducing Si; and
nitriding said metal film introduced with Si in said second chamber.

13. The semiconductor device manufacturing method according to claim 12, wherein
radicals formed by bringing treatment gas into a plasma state with use of a microwave are used for said reduction treatment of the surface of said metal film.

14. The semiconductor device manufacturing method according to claim 12, wherein
a thermochemical method supplying treatment gas with heating the semiconductor substrate is used for said reduction treatment of the surface of said metal film.

15. The semiconductor device manufacturing method according to claim 13, wherein
said treatment gas contains at least either hydrogen or ammonia.

16. The semiconductor device manufacturing method according to claim 11, wherein
said semiconductor substrate is carried with vacuum being held between said first chamber and said second chamber.

17. The semiconductor device manufacturing method according to claim 1, wherein
said step of depositing a metal film is performed in a first chamber;
said step of introducing Si into said metal film is performed in a second chamber; and
said step of nitriding said metal film introduced with Si is performed in a third chamber.

18. The semiconductor device manufacturing method according to claim 17, further comprising the steps of:
performing reduction treatment of a surface of said metal film prior to said steps of introducing Si; and
nitriding said metal film introduced with Si in said second chamber.

19. The semiconductor device manufacturing method according to claim 18, wherein
radicals formed by bringing treatment gas into a plasma state with use of a microwave are used for said reduction treatment of the surface of said metal film.

20. The semiconductor device manufacturing method according to claim 18, wherein
a thermochemical method supplying treatment gas with heating the semiconductor substrate is used for said reduction treatment of the surface of said metal film.

21. The semiconductor device manufacturing method according to claim 19, wherein
said treatment gas contains at least either hydrogen or ammonia.

22. The semiconductor device manufacturing method according to claim 17, wherein
said semiconductor substrate is carried with vacuum being respectively held between said first chamber and said second chamber and between said second chamber and said third chamber.

23. A semiconductor device manufacturing apparatus comprising:
a chamber:
wherein the chamber includes
a depositing means adapted to deposit a metal film consisting essentially of tungsten (W) on a copper or copper-containing metal film exposed on a surface of a semiconductor substrate,
an introducing means adapted to introduce Si into said metal film and
a nitriding means adapted to nitride said metal film introduced with Si.

24. A semiconductor device manufacturing apparatus comprising:
a first chamber provided with a depositing means adapted to deposit a metal film consisting essentially of tungsten (W) on a copper or copper-containing metal film exposed on a surface of a semiconductor substrate and an introducing means adapted to introduce Si into said metal film;
a second chamber provided with a nitriding means adapted to nitride said metal film introduced with Si; and
a carrying mechanism adapted to carry said semiconductor substrate with vacuum being held between said first chamber and said second chamber.

25. A semiconductor device manufacturing apparatus comprising:
a first chamber provided with a depositing means adapted to deposit a metal film consisting essentially of any of cobalt-tungsten based metal (CoW) or tungsten (W) on a copper or copper-containing metal film exposed on a surface of a semiconductor substrate;
a second chamber provided with an introducing means adapted to introduce Si into said metal film and a nitriding means adapted to nitride said metal film introduced with Si; and
a carrying mechanism adapted to carry said semiconductor substrate between said first chamber and said second chamber.

26. A semiconductor device manufacturing apparatus comprising:
a first chamber provided with a depositing means adapted to deposit a metal film consisting essentially of either cobalt-tungsten based metal (CoW) or tungsten (W) on a copper or copper-containing metal film exposed on a surface of a semiconductor substrate;
a second chamber provided with an introducing means adapted to introduce Si into said metal film;
a third chamber provided with a nitriding means adapted to nitride said metal film introduced with Si; and
a carrying mechanism adapted to carry said semiconductor substrate with vacuum being held at least between said second chamber and said third chamber of between said first chamber and said second chamber and between said second chamber and said third chamber.
